(19) United States
(12) Patent Application Publication
(10) Pub. No.: US 2021/0036252 A1
(43) Pub. Date: Feb. 4, 2021

(54) SEMICONDUCTOR FILM, OPTICAL SENSOR, SOLID-STATE IMAGE SENSOR, AND SOLAR BATTERY

(71) Applicant: SONY CORPORATION, TOKYO (JP)

(72) Inventors: SYUUITI TAKIZAWA, TOKYO (JP); MICHINORI SHIOMI, KANAGAWA (JP); DAISUKE HOBARA, KANAGAWA (JP); MASANORI SAKAMOTO, KYOTO (JP); TOSHIHARU TERANISHI, KYOTO (JP)

(21) Appl. No.: 16/964,092

(22) PCT Filed: Feb. 5, 2019
(86) PCT No.: PCT/JP2019/004010

§ 371 Date: Jul. 22, 2020

(30) Foreign Application Priority Data
Feb. 5, 2018 (JP) 2018-018657

(51) Int. Cl. H01L 51/44; H01L 27/30; C09K 11/88; C09K 11/62; H01L 51/42; B82Y 20/00; B82Y 40/00

(52) U.S. Cl. CPC H01L 51/447; H01L 27/307; C09K 11/883; B82Y 40/00; H01L 51/442; H01L 51/426; B82Y 20/00; C09K 11/623

(57) ABSTRACT

It is an object of the present technology to provide a semiconductor film capable of further improving photoelectric conversion efficiency. There is provided a semiconductor film containing semiconductor nanoparticles and sulfur, the semiconductor nanoparticles having a core-shell structure, the core portion containing a compound represented by the following general formula (1), the shell portion containing ZnS, the sulfur coordinating to the semiconductor nanoparticles.

(Chem. 1)

Cu_{y1}In_{z1}A1_{(y1+3z1)/2} (1)

(In the general formula (1), y1 satisfies a relationship of 0<y1≤20, z1 satisfies a relationship of 0<z1≤20, and A1 represents S, Se, or Te.)

### TECHNICAL FIELD

The present technology relates to a semiconductor film, an optical sensor, a solid-state image sensor, and a solar battery.

### BACKGROUND ART

In recent years, in order to realize ultra-small size and high image quality of digital cameras or the like, research and development of a color imaging device in which red, blue, and green absorption layers are staked is underway. Further, in order to realize a solar battery having high efficiency, a solar battery in which films that efficiently absorb a specific wavelength are stacked, e.g., a multi-stacked solar battery has been developed.

As a typical quantum dot that absorbs visible light, a CdSe quantum dot (see Non-Patent Literature 1.), a PbS quantum dot (see Non-Patent Literature 2.), an a CuInS2 quantum dot (see Non-Patent Literature 3.) have been reported. As a typical ligand that brings quantum dots close to each other, an organic ligand having a mercapto group (see Patent Literature 1.), a thiocyanate ligand (see Non-Patent Literature 4), and a sulfur ligand (see Non-Patent Literatures 5 to 7) have been reported.

### CITATION LIST

### Patent Literature

Patent Literature 1: Japanese Patent Application Laid-open No. 2014-112623

### Non-Patent Literature

Non-Patent Literature 1: J. Phys. Chem. C 2014, 118, 214-222

Non-Patent Literature 2: Nature photonics 2011, 5, 480-484

Non-Patent Literature 3: J. Am. Chem. Soc. 2014, 136, 9203-9210

Non-Patent Literature 4: Nano Lett. 2012, 12, 2631-2638

Non-Patent Literature 5: ACS Appl. Mater. Interfaces 2013, 5, 3143-3148

Non-Patent Literature 6: Nano Lett. 2012, 12, 1813-1820

Non-Patent Literature 7: Nano Lett. 2011, 11, 5356-5361

### DISCLOSURE OF INVENTION

### Technical Problem

However, in the technologies proposed in Patent Literature 1 and Non-Patent Literatures 1 to 7, there is a possibility that photoelectric conversion efficiency cannot be further improved.

In this regard, the present technology has been made in view of the above-mentioned circumstances and it is a main object thereof to provide a semiconductor film capable of further improving photoelectric conversion efficiency and an optical sensor, a solid-state image sensor, and a solar battery having high photoelectric conversion efficiency.

### Solution to Problem

The present inventors have intensively conducted research in order to achieve the above-mentioned object, and it is surprising that the present inventors have succeeded in dramatically improving photoelectric conversion efficiency as a result thereof. Thus, they have completed the present technology.

That is, in the present technology, first, there is provided a semiconductor film containing semiconductor nanoparticles and sulfur, the semiconductor nanoparticles having a core-shell structure, the core portion containing a compound represented by the following general formula (1), the shell portion containing ZnS, the sulfur coordinating to the semiconductor nanoparticles.

(Chem. 1)

Cu_{y1}In_{z1}A1_{(y1+3z1)/2} (1)

(In the general formula (1), y1 satisfies a relationship of 0<y1≤20, z1 satisfies a relationship of 0<z1≤20, and A1 represents S, Se, or Te.)

Further, in the present technology, there is provided a semiconductor film containing semiconductor nanoparticles and sulfur, the semiconductor nanoparticles having a core-shell structure, the core portion containing a compound represented by the following general formula (2), the shell portion containing ZnS, the sulfur coordinating to the semiconductor nanoparticles.

(Chem. 2)

Znₓ₁Cu_{y2}In_{z2}A2_{(2x1+y2+3z2)/2} (2)

(In the general formula (2), x1 satisfies a relationship of 0<x1≤20, y2 satisfies a relationship of 0<y2≤20, z2 satisfies a relationship of 0<z2≤20, and A2 represents S, Se, or Te.)

Further, in the present technology, there is provided a semiconductor film containing semiconductor nanoparticles and sulfur, the semiconductor nanoparticles containing a compound represented by the following general formula (3), the sulfur coordinating to the semiconductor nanoparticles.

(Chem. 3)

Znₓ₂Cu_{y3}In_{z3}A3_{(2x2+y3+3z3)/2} (3)

(In the general formula (3), x2 satisfies a relationship of 0<x2≤20, y3 satisfies a relationship of 0<y3≤20, z3 satisfies a relationship of 0<z3≤20, and A3 represents S, Se, or Te.)

In the present technology, there is provided an optical sensor, including: the semiconductor film according to the present technology; and a first electrode and a second electrode that are disposed to face each other, in which the semiconductor film is disposed between the first electrode and the second electrode.

Further, in the present technology, there is provided a solid-state image sensor, including:

at least the optical sensor according to the present technology and a semiconductor substrate stacked for each of a plurality of one- or two-dimensionally arranged pixels.

Further, in the present technology, there are provided a solid-state image sensor, including: the one optical sensor according to the present technology and a semiconductor substrate stacked for each of a plurality of one- or two-dimensionally arranged pixels, in which the optical sensor is for blue,

a solid-state image sensor, including: the two optical sensors according to the present technology and a semiconductor substrate stacked for each of a plurality of one- or two-dimensionally arranged pixels, in which the optical sensors are for blue and green, and

a solid-state image sensor, including: the three optical sensors according to the present technology and a semiconductor substrate stacked for each of a plurality of one- or two-dimensionally arranged pixels, in which the optical sensors are for blue, green, and red.

Then, in the present technology, there is provided a solar battery, including: at least

the semiconductor film according to the present technology; and a first electrode and a second electrode that are arranged to face each other, in which the semiconductor film is disposed between the first electrode and the second electrode.

### Advantageous Effects of Invention

In accordance with the present technology, it is possible to improve photoelectric conversion efficiency. It should be noted that the effect described here is not necessarily limitative and may be any effect described in the present disclosure.

### BRIEF DESCRIPTION OF DRAWINGS

FIG. 1 is a diagram schematically showing an example of a method of producing a semiconductor film to which the present technology is applied.

FIG. 2 is a cross-sectional view showing a configuration example of a solid-state image sensor (corresponding to one pixel) to which the present technology is applied.

FIG. 3 is an explanatory diagram describing an operation of the solid-state image sensor to which the present technology is applied.

FIG. 4 is a cross-sectional view showing a first modified example (modified example 1) of the solid-state image sensor (corresponding to one pixel) shown in FIG. 2.

FIG. 5 is a cross-sectional view showing a second modified example (modified example 2) of the solid-state image sensor (corresponding to one pixel) shown in FIG. 2.

FIG. 6 is a functional block diagram of the solid-state image sensor to which the present technology is applied.

FIG. 7 is a cross-sectional view schematically showing a configuration example of an optical sensor prepared in Example 6.

FIG. 8 is a diagram showing the results of Example 7.

FIG. 9 is a diagram showing the results of Example 8.

FIG. 10 is a diagram showing the results of Example 8.

FIG. 11 is a diagram showing a usage example of the solid-state image sensor to which the present technology is applied.

FIG. 12 is a functional block diagram of an example of an electronic apparatus to which the present technology is applied.

### MODE(S) FOR CARRYING OUT THE INVENTION

Hereinafter, favorable embodiments for carrying out the present technology will be described. The embodiments described below show an example of the typical embodiment of the present technology, and the scope of the present technology is not narrowly construed by the embodiments.

Note that description will be made in the following order.

1. Overview of present technology

2. First embodiment(example 1 of semiconductor film)

3. Second embodiment(example 2 of semiconductor film)

4. Third embodiment(example 3 of semiconductor film)

5. Fourth embodiment(example 1 of optical sensor)

6. Fifth embodiment(example 2 of optical sensor)

7. Sixth embodiment(example 3 of optical sensor)

8. Seventh embodiment(example 1 of solid-state image sensor)

9. Eighth embodiment(example 2 of solid-state image sensor)

10. Ninth embodiment(example 3 of solid-state image sensor)

11. Tenth embodiment(example 1 of solar battery)

12. Eleventh embodiment(example 2 of solar battery)

13. Twelfth embodiment(example 3 of solar battery)

14. Thirteenth embodiment(example of electronic apparatus)

15. Usage example of solid-state image sensor to which present technology is applied

### 1. Overview of Present Technology

First, an overview of the present technology will be described.

In order to improve the performance of color imaging devices installed in digital cameras or the like and diversify the functions thereof, it is necessary to advance the technology relating to an optical sensor or a photoelectric conversion element using semiconductor nanoparticles.

In an image sensor, e.g., a vertical spectral image sensor, or a solar battery, e.g., a multi-stacked solar battery, in order to develop a quantum dot film (semiconductor film) that has selectivity for the absorption edge wavelength and is capable of efficiently transporting generated carriers to electrodes, it is necessary to improve the technology relating to control of the absorption wavelength, high carrier transfer, and the like.

In order to control the absorption edge wavelength of a semiconductor film (which may be a photoelectric conversion film.), for example, the diameter size of particles (core portion) of the compound represented by the general formula (1) (Cuy1Inz1A1(y1+3z1)/2, e.g., CuInS₂) in the case of semiconductor nanoparticles in which the core portion contains a compound represented by the following general formula (1) and the shell portion contains ZnS is changed in the present technology, thereby making it possible to control the absorption edge wavelength. The average particle size of the semiconductor nanoparticles in which the core portion contains the compound represented by the following general formula (1) and the shell portion contains ZnS can be measured by, for example, observing the particle shapes with a TEM (Transmission Electron Microscope) image. Further, also by changing the ratio of y1 and z1, the absorption edge wavelength can be controlled.

For example, the absorption edge wavelength can be controlled by changing the diameter size of particles (core portion) of the compound represented by the general formula (2) (Znₓ₁Cu_{y2}In_{z2}A2_{(2x1+y2+3z2)/2}) in the case of semiconductor nanoparticles in which the core portion contains the compound represented by the following general formula (2) and the shell portion contains ZnS. The average particle size of the semiconductor nanoparticles in which the core portion contains the compound represented by the following general formula (2) and the shell portion contains ZnS can be measured by, for example, observing the particle shapes with a TEM (Transmission Electron Microscope) image. Further, also by changing the ratio of x1, y2, z2, the ratio of x1 and y2, the ratio of x1 and z2, or the ratio of y2 and z2, the absorption edge wavelength can be controlled.

Further, the absorption edge wavelength can be controlled by chancing the diameter size of particles of the compound represented by the general formula (3) (Znₓ₂Cu_{y3}In_{z3}A3_{(2x2+y3+3z3)/2)} in the case of semiconductor nanoparticles of the compound represented by the following general formula (3) (Znₓ₂Cu_{y3}In_{z3}A3_{(2x2+y3+3z3)/2}, ZnCuInS₃ formed of a mixed crystal of CuInS₂ and ZnS). The average particle size of the semiconductor nanoparticles containing the compound represented by the following general formula (3) can be measured by, for example, observing the particle shapes with a TEM (Transmission Electron Microscope) image. Further, the absorption edge wavelength can be controlled by changing the ratio (composition ratio) of Cu_{y3}In_{z3}S_{(y3+3z3)/2} (e.g., CuInS₂) and Znₓ₂Sₓ₂ (e.g., ZnS) (examples thereof include Zn_{0.5}CuInS_{2.5}).

(Chem. 4)

Cu_{y1}In_{z1}A1_{(y1+3z1)/2} (1)

(In the general formula (1), y1 satisfies the relationship of 0<y1≤20, z1 satisfies the relationship of 0<z1≤20, and A1 represents S, Se, or Te.)

(Chem. 5)

Znₓ₁Cu_{y2}In_{z2}A2_{(2x1+y2+3z2)/2} (2)

(In the general formula (2), x1 satisfies the relationship of 0<x1≤20, y2 satisfies the relationship of 0<y2≤20, z2 satisfies the relationship of 0<z2≤20, and A2 represents S, Se, or Te.)

(Chem. 6)

Znₓ₂Cu_{y3}In_{z3}A3_{(2x2+y3+3z3)/2} (3)

(In the general formula (3), x2 satisfies the relationship of 0<x2≤20, y3 satisfies the relationship of 0<y3≤20, z3 satisfies the relationship of 0<z3≤20, and A3 represents S, Se, or Te.)

Further, in order to improve the mobility of carriers, a semiconductor film is formed by using sulfur (S) that is a short ligand as the ligand of the above-mentioned quantum dot (semiconductor nanoparticles), thereby making the distance between quantum dots (semiconductor nanoparticles) short to realize high carrier mobility. Then, since the high carrier mobility is realized, the response characteristics during photoelectric conversion is improved and an optical sensor, a solid-state image sensor, and a solar battery having high photoelectric conversion efficiency can be obtained.

Regarding the semiconductor film according to the present technology, semiconductor nanoparticles in which a core portion contains the above-mentioned compound represented by the general formula (1) and a shell portion contains ZnS, semiconductor nanoparticles in which a core portion contains the above-mentioned compound represented by the general formula (2) and a shell portion contains ZnS, and semiconductor nanoparticles (quantum dot) containing represented by the above-mentioned compound represented by the general formula (3) of a long-chain ligand obtained by synthesis is treated with an ammonium sulfide aqueous solution, and thus, dispersion liquids of the above-mentioned three types of semiconductor nanoparticles (quantum dots) having sulfur (S) coordination can be prepared.

Then, these three dispersion liquids can be deposited on, for example, a substrate to prepare a semiconductor film according to the present technology. An optical sensor, a solid-state image sensor, and a solar battery according to the present technology can be prepared using the semiconductor film according to the present technology. Since the optical sensor, the solid-state image sensor, and the solar battery according to the present technology includes a semiconductor film capable of further improving photoelectric conversion efficiency, they have excellent photoelectric conversion efficiency.

### 2. First Embodiment (Example 1 of Semiconductor Film)

A semiconductor film of a first embodiment (example 1 of semiconductor film) according to the present technology contains semiconductor nanoparticles and sulfur, the semiconductor nanoparticles having a core-shell structure, the core portion containing the compound represented by the following general formula (1), the shell portion containing ZnS, sulfur coordinating to the semiconductor nanoparticles.

(Chem. 7)

Cu_{y1}In_{z1}A1_{(y1+3z1)/2} (1)

(In the general formula (1), y1 satisfies the relationship of 0<y1≤20, z1 satisfies the relationship of 0<z1≤20, and A1 represents S, Se, or Te.)

In the above-mentioned general formula (1), the molar ratio of Cu/In may have an arbitrary value. However, from the viewpoint of further improving photoelectric conversion efficiency, the molar ratio of Cu/In is favorably 1.5 or less and more favorably 0.3 to 1.

In accordance with the semiconductor film of the first embodiment according to the present technology, the effects of excellent absorption wavelength selectivity and excellent carrier mobility are exhibited, and high photoelectric conversion efficiency can be realized. Further, since sulfur is coordinated in the semiconductor film of the first embodiment according to the present technology, it is possible to prevent heat resistance, solvent resistance, and robustness during the process from being reduced. Further, it is possible to improve the safety because no toxic heavy element is used.

(Method of Producing Semiconductor Film of First Embodiment According to Present Technology)

A method of producing a semiconductor film of a first embodiment according to the present technology is a production method including depositing (coating) a dispersion liquid in which semiconductor nanoparticles are dispersed in a solvent on a substrate, the semiconductor nanoparticles having a core-shell structure, the core portion containing the above-mentioned compound represented by the general formula (1), the shell portion containing ZnS, sulfur (S) coordinating to the semiconductor nanoparticles.

The solvent may be a polar solvent. The polar solvent may be optional. However, examples thereof include methanol, ethanol, N,N-dimethylformamide, dimethyl sulfoxide, N-methylformamide, butylamine, and amines having a small number of carbon atoms.

The above-mentioned substrate on which the dispersion liquid is to be coated represents a concept including an electrode, and a single-layer structure in which the substrate itself is an electrode or a stacked structure in which an electrode is stacked on a support substrate formed of an inorganic material, a resin, or the like may be adopted. Further, the substrate may have a stacked structure in which an electrode and an insulation film are stacked on a support substrate formed of an inorganic material, a resin, or the like. The shape, size, and thickness of the substrate are not particularly limited, and can be appropriately selected depending on the viewpoint of the production suitability, the purpose of use, and the like.

Specific examples of the method of depositing (coating) the semiconductor film include a wet coating method. Here, specific examples of the coating method include a spin coat method; a dipping method; a cast method; various printing methods such as a screen printing method, an inkjet method, an offset printing method, and a gravure printing method; a stamp method; a spray method; an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method.

(Specific Example of Producing Semiconductor Film of First Embodiment According to Present Technology)

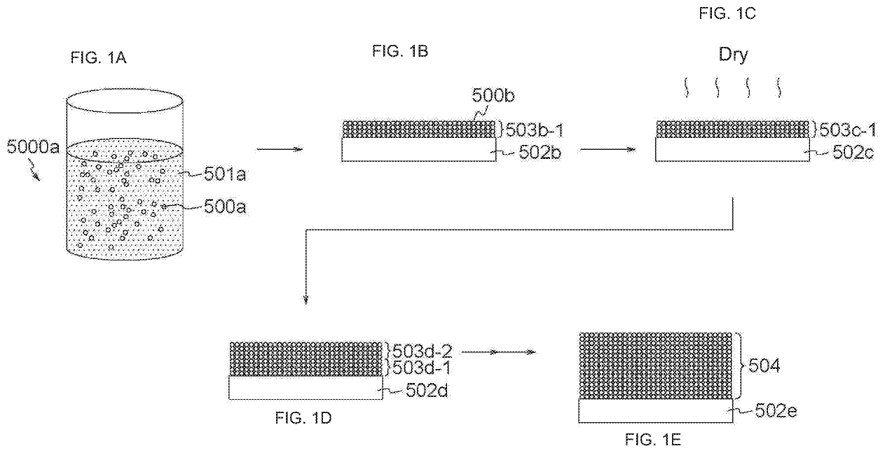

A specific example of the method of producing the semiconductor film of the first embodiment according to the present technology will be described with reference to FIG. 1. The method of producing the semiconductor film shown in FIG. 1 is a so-called Layer-by-Layer (LBL) method. As shown in FIG. 1, a semiconductor film is produced in the order of (a)→(b)→(c)→(d)→(e).

Part (a) of FIG. 1 is a diagram showing a prepared dispersion liquid 5000a. As shown in Part (a) of FIG. 1, semiconductor nanoparticles 500a (semiconductor nanoparticles in which a core portion is CnInS₂ and a shell portion is ZnS) to which sulfur (S) coordinates are dispersed in a solvent 501a of N,N-dimethylformamide (DMF).

Next, as shown in Part (b) of FIG. 1, the dispersion liquid 5000a is coated on an electrode (substrate) 502b (e.g., TiO₂) as a first layer by a spin coat method, and a film 503b-1 containing semiconductor nanoparticles 500b is deposited on the electrode (substrate) 502b.

Subsequently, in Part (c) of FIG. 1, the film 503c-1 is dried. The semiconductor nanoparticles 500c on the electrode (substrate) 502c aggregate and are insolubilized in the film 503c-1.

In Part (d) of FIG. 1, the dispersion liquid 5000a is coated and stacked, as a second layer, on the film 503d-1 of the first layer by a spin coat method, and the film 503d-1 of the first layer and a film 503d-2 of the second layer are deposited on the electrode (substrate) 502b.

As shown in Part (e) of FIG. 1, the dispersion liquid 5000a is repeatedly coated as layers on the electrode (substrate) 502e by a spin coat method to have a predetermined film thickness, and thus, a semiconductor film 504 having a predetermined film thickness is produced.

### 3. Second Embodiment (Example 2 of Semiconductor Film)

A semiconductor film of a second embodiment (example 2 of semiconductor film) according to the present technology is a semiconductor film containing semiconductor nanoparticles and sulfur, the semiconductor nanoparticles having a core-shell structure, the core portion containing a compound represented by the following general formula (2), the shell portion containing ZnS, sulfur coordinating to the semiconductor nanoparticles.

(Chem. 8)

Znₓ₁Cu_{y2}In_{z2}A2_{(2x1+y2+3z2)/2} (2)

(In the general formula (2), x1 satisfies the relationship of 0<x1≤20, y2 satisfies the relationship of 0<y2≤20, z2 satisfies the relationship of 0<z2≤20, and A2 represents S, Se, or Te.)

In the above-mentioned general formula (2), the molar ratio of Cu/In may have an arbitrary value. However, from the viewpoint of further improving photoelectric conversion efficiency, the molar ratio of Cu/In is favorably 1.5 or less and more favorably 0.3 to 1.

In accordance with the semiconductor film of the second embodiment according to the present technology, the effects of the effects of excellent absorption wavelength selectivity and excellent carrier mobility are exhibited, and high photoelectric conversion efficiency can be realized. Further, since sulfur is coordinated in the semiconductor film of the second embodiment according to the present technology, it is possible to prevent heat resistance, solvent resistance, and robustness during the process from being reduced. Further, it is possible to improve the safety because no toxic heavy element is used.

(Method of Producing Semiconductor Film of Second Embodiment According to Present Technology)

A method of producing the semiconductor film of the second embodiment according to the present technology is a production method including depositing (coating) a dispersion liquid in which semiconductor nanoparticles are dispersed in a solvent on a substrate, the semiconductor nanoparticles having a core-shell structure, the core portion containing the above-mentioned compound represented by the above-mentioned general formula (2), the shell portion containing ZnS, sulfur (S) coordinating to the semiconductor nanoparticles.

Since the solvent, substrate, and deposition (coating) method used in the method of producing the semiconductor film of the second embodiment according to the present technology are similar to the solvent, substrate, and deposition (coating) method used in the method of producing the semiconductor film of the first embodiment according to the present technology and are as described above, description thereof is omitted here.

Note that the specific example of the method of producing the semiconductor film of the first embodiment according to the present technology shown in FIG. 1 is applicable also to the method of producing the semiconductor film of the second embodiment according to the present technology.

### 4. Third Embodiment (Example 3 of Semiconductor Film)

A semiconductor film of a third embodiment (example 3 of semiconductor film) according to the present technology is a semiconductor film containing semiconductor nanoparticles and sulfur, the semiconductor nanoparticles containing a compound represented by the following general formula (3), the sulfur coordinating to the semiconductor nanoparticles.

(Chem. 9)

Znₓ₂Cu_{y3}In_{z3}A3_{(2x2+y3+3z3)/2} (3)

(In the general formula (3), x2 satisfies a relationship of 0<x2≤20, y3 satisfies the relationship of 0<y3≤20, z3 satisfies a relationship of 0<z3≤20, and A3 represents S, Se, or Te.)

In the above-mentioned general formula (3), the molar ratio of Cu/In may have an arbitrary value. However, from the viewpoint of further improving photoelectric conversion efficiency, the molar ratio of Cu/In is favorably 1.5 or less and more favorably 0.3 to 1.

In accordance with the semiconductor film of the third embodiment according to the present technology, the effects of excellent absorption wavelength selectivity and excellent carrier mobility are exhibited, and high photoelectric conversion efficiency can be realized. Further, since sulfur is coordinated in the semiconductor film of the third embodiment according to the present technology, it is possible to prevent heat resistance, solvent resistance, and robustness during the process from being reduced. Further, it is possible to improve the safety because no toxic heavy element is used.

(Method of Producing Semiconductor Film of Third Embodiment According to Present Technology)

A method of producing a semiconductor film of the third embodiment according to the present technology is a production method including depositing (coating) a dispersion liquid in which semiconductor nanoparticles are dispersed in a solvent on a substrate, the semiconductor nanoparticles containing the compound represented by the above-mentioned general formula (3), sulfur (S) coordinating to the semiconductor nanoparticles.

Since the solvent, substrate, and deposition (coating) method used in the method of producing the semiconductor film of the third embodiment according to the present technology are similar to the solvent, substrate, and deposition (coating) method used in the method of producing the semiconductor film of the first embodiment according to the present technology and are as described above, description thereof is omitted here.

Note that the specific example of the method of producing the semiconductor film of the first embodiment according to the present technology shown in FIG. 1 is applicable also to the method of producing the semiconductor film of the third embodiment according to the present technology.

### 5. Fourth Embodiment (Examples 1 of Optical Sensor)

An optical sensor of a fourth embodiment (example 1 of optical sensor) according to the present technology is an optical sensor including: the semiconductor film of the first embodiment according to the present technology; and a first electrode and a second electrode that are disposed to face each other, in which the semiconductor film is disposed between the first electrode and the second electrode. In this case, the semiconductor film may act as a photoelectric conversion film (photoelectric conversion layer). As described below, an electron transport layer may be disposed between the first electrode and the semiconductor film, and a hole transport layer may be disposed between the second electrode and the semiconductor film.

Note that since the semiconductor film of the first embodiment included in the optical sensor of the fourth embodiment according to the present technology is as described above, description thereof is omitted here.

Since the optical sensor of the fourth embodiment according to the present technology includes the semiconductor film of the first embodiment, it has excellent photoelectric conversion efficiency. Examples of the optical sensor of the fourth embodiment according to the present technology include an optical sensor for blue, an optical sensor for green, an optical sensor for red.

(First Electrode)

The first electrode included in the optical sensor of the fourth embodiment according to the present technology is one take out signal charges (charges) generated in the semiconductor film. The first electrode is formed of, for example, a conductive material having a light transmission property, specifically, ITO (Indium-Tin-Oxide). The first electrode may be formed of, for example, a tin oxide (SnO₂) material or a zinc oxide (ZnO) material. The tin oxide material is one obtained by adding a dopant to tin oxide, and the zinc oxide material is, for example, aluminum zinc oxide (AZO) obtained by adding aluminum (Al) as a dopant to zinc oxide, a gallium zinc oxide (GZO) obtained by adding gallium (Ga) as a dopant to zinc oxide, or an indium zinc oxide (IZO) obtained by adding indium (In) as a dopant to zinc oxide. In addition, IGZO, CuI, InSbO₄, ZnMgO, CuInO₂, MgIn₂O₄, CdO, ZnSnO₃, or the like can be used. The thickness (thickness in the stacking direction, hereinafter, referred to simply as thickness) of the first electrode may be an arbitrary thickness, but is, for example, 50 nm to 500 nm.

(Second Electrode)

The second electrode included in the optical sensor of the fourth embodiment according to the present technology is for taking out holes. The second electrode may be formed of, for example, a conductive material such as gold (Au), silver (Ag), copper (Cu), and aluminum (Al). Similarly to the first electrode, the second electrode may be formed of a transparent conductive material. The thickness of the second electrode may be an arbitrary thickness, but is, for example, 0.5 nm to 100 nm.

(Electron Transport Layer)

The electron transport layer that may be included in the optical sensor of the fourth embodiment according to the present technology is for promoting the supply of electrons generated in the semiconductor film to the first electrode, and may be formed of, for example, titanium oxide (TiO₂) or zinc oxide (ZnO). The electron transport layer may be formed by stacking titanium oxide and zinc oxide. The thickness of the electron transport layer may be an arbitrary thickness, but is, for example, 0.1 nm to 1000 nm and favorably 0.5 nm to 200 nm.

(Hole Transport Layer)

The hole transport layer that may be included in the optical sensor of the fourth embodiment according to the present technology is for promoting the supply of holes generated in the semiconductor film to the second electrode, and may be formed of, for example, molybdenum oxide (MoO₃), nickel oxide (NiO), or vanadium oxide (V₂O₅). The hole transport layer may be formed of an organic material such as PEDOT (Poly(3,4-ethylenedioxythiophene)), TPD (N,N′-Bis(3-methylphenyl)-N,N′-diphenylbenzidine), or the like. The thickness of the hole transport layer may be an arbitrary thickness, but is, for example, 0.5 nm to 100 nm.

(Substrate for Optical Sensor)

An optical sensor may be formed on the substrate. Here, examples of the material of the substrate include an organic polymer (having a form of a polymer material, such as a plastic film, a plastic sheet, and a plastic substrate, which is formed of a polymer material and has flexibility) exemplified by polymethylmethacrylate (polymethylmethacrylate, PMMA), polyvinyl alcohol (PVA), polyvinylphenol (PVP), polyether sulfone (PES), polyimide, polycarbonate (PC), polyethylene terephthalate (PET), and polyethylene naphthalate (PEN). By using a substrate formed of such a polymer material having flexibility, for example, it is possible to incorporate or integrate an image sensor into an electronic apparatus having a curved shape. Alternatively, examples of the substrate include various glass substrates, various glass substrates having an insulation film formed on the surface thereof, a quartz substrate, a quartz substrate having an insulation film formed on the surface thereof, a silicon semiconductor substrate, and metal substrates formed of various alloys such as stainless steel having an insulation film formed on the surface thereof or various metals. Note that examples of the material of the insulation film include a silicon oxide material (e.g., SiOₓ and spin-on glass (SOG)); silicon nitride (SiN_{y}); silicon oxynitride (SiON); aluminum oxide (Al₂O₃); a metal oxide, and a metal salt. Further, it is also possible to form an organic insulation film. Examples of the material of such an organic insulation film include a lithography-enabled polyphenolic material, polyvinylphenol material, polyimide material, polyamide material, polyamide imide material, fluorine polymer material, borazine-silicon polymer material, and truxene material. Further, a conductive substrate (a substrate formed of a metal such as gold and aluminum, a substrate formed of highly oriented graphite) having such an insulation film is formed on the surface thereof can be used.

The surface of the substrate is favorably smooth, but may have a roughness that does not adversely affect the characteristics of the organic photoelectric conversion layer. By forming, on the surface of the substrate, a silanol derivative by a silane coupling method, a thin film formed of a thiol derivative, a carboxylic acid derivative, a phosphoric acid derivative, or the like by a SAM method or the like, or a thin film formed of an insulating metal salt or metal complex by a CVD method or the like, the adhesion between the first electrode and the substrate or the adhesion between the second electrode and the substrate may be improved.

(Method of Producing Optical Sensor)

A method of producing the optical sensor of the fourth embodiment according to the present technology will be described. Here, a case where the optical sensor of the fourth embodiment according to the present technology includes an electron transport layer and a hole transport layer will be described.

First, a first electrode is formed. Note that in the case where the optical sensor is formed on the substrate described above, a first electrode can be formed on a substrate for an optical sensor. The first electrode is formed by, for example, depositing an ITO film by a sputtering method and then patterning this by a photolithography technology and performing dry etching or wet etching.

Subsequently, an electron transport layer formed of, for example, titanium oxide on the first electrode, and then, a semiconductor film is formed. The semiconductor film is formed by being coated on the electron transport layer by a wet deposition method and then performing heat treatment thereon. Examples of the wet deposition method include various coating methods such as a spin coat method, a dipping method, a cast method, various printing methods such as a screen printing method, an inkjet method, an offset printing method, and a gravure printing method, a stamp method, a spray method, an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method. The heat treatment is performed in the atmosphere under a nitrogen (N₂) atmosphere or under an argon (Ar) atmosphere at, for example, 100° C. for 30 minutes.

After providing the semiconductor film, for example, molybdenum oxide, nickel oxide, or the like is deposited to form a hole transport layer. A second electrode is formed by depositing a conductive film on this hole transport layer by a vacuum vapor deposition method, thereby producing an optical sensor.

### 6. Fifth Embodiment (Example 2 of Optical Sensor)

An optical sensor of a fifth embodiment (example 2 of optical sensor) according to the present technology is an optical sensor including: the semiconductor film of the second embodiment according to the present technology; and a first electrode and a second electrode that are disposed to face each other, in which the semiconductor film is disposed between the first electrode and the second electrode. In this case, the semiconductor film may act as a photoelectric conversion film (photoelectric conversion layer). Since the first electrode and the second electrode are similar to the first electrode and the second electrode used in the fourth embodiment according to the present technology and are as described above, description thereof is omitted here.

Since the optical sensor of the fifth embodiment according to the present technology includes the semiconductor film according to the second embodiment, it has excellent photoelectric conversion efficiency. Examples of the optical sensor of the fifth embodiment according to the present technology include an optical sensor for blue, an optical sensor for green, and an optical sensor for red.

In the optical sensor of the fifth embodiment according to the present technology, an electron transport layer may be disposed between the first electrode and the semiconductor film and a hole transport layer may be disposed between the second electrode and the semiconductor film. Since the electron transport layer and the hole transport layer are similar to the electron transport layer and the hole transport layer used in the optical sensor of the fourth embodiment according to the present technology and are as described above, description thereof is omitted here.

Further, since the semiconductor film of the second embodiment included in the optical sensor of the fifth embodiment according to the present technology is as described above, description thereof is omitted here.

Further, the substrate for an optical sensor that may be included in the optical sensor of the fifth embodiment according to the present technology is similar to the substrate that may be included in the optical sensor of the fourth embodiment according to the present technology and is as described above, description thereof is omitted here. Then, the method of producing the optical sensor of the fourth embodiment according to the present technology described above is appliable also to the method of producing the optical sensor of the fifth embodiment according to the present technology.

### 7. Sixth Embodiment (Example 3 of Optical Sensor)

An optical sensor of a sixth embodiment (example 3 of optical sensor) according to the present technology is an optical sensor including: the semiconductor film of the third embodiment according to the present technology; and a first electrode and a second electrode that are disposed to face each other, in which the semiconductor film is disposed between the first electrode and the second electrode. In this case, the semiconductor film may act as a photoelectric conversion film (photoelectric conversion layer). Since the first electrode and the second electrode are similar to the first electrode and the second electrode used in the optical sensor of the fourth embodiment according to the present technology and are as described above, description thereof is omitted here.

Since the optical sensor of the sixth embodiment according to the present technology includes the semiconductor film of the third embodiment, it has excellent photoelectric conversion efficiency. Examples of the optical sensor of the sixth embodiment according to the present technology include an optical sensor for blue, an optical sensor for green, and an optical sensor for red.

In the optical sensor of the sixth embodiment according to the present technology, an electron transport layer may be disposed between the first electrode and the semiconductor film and a hole transport layer may be disposed between the second electrode and the semiconductor film. Since the electron transport layer and the hole transport layer are the same as the electron transport layer and the hole transport layer used in the optical sensor of the fourth embodiment according to the present technology, description thereof is omitted here.

Note that since the semiconductor film of the third embodiment included in the optical sensor of the sixth embodiment according to the present technology is as described above, description thereof is omitted here.

Further, since the substrate for an optical sensor that may be included in the optical sensor of the sixth embodiment according to the present technology is similar to the substrate that may be included in the optical sensor of the fourth embodiment according to the present technology and is as described above, description thereof is omitted here. Then, the method of producing the optical sensor of the fourth embodiment according to the present technology described above is applicable also to the method of producing the optical sensor of the sixth embodiment according to the present technology.

### 8. Seventh Embodiment (Example 1 of Solid-State Image Sensor)

A solid-state image sensor of a seventh embodiment (example 1 of solid-state image sensor) according to the present technology is a solid-state image sensor including: at least the optical sensor of the fourth embodiment according to the present technology and a semiconductor substrate stacked for each of a plurality of one- or two-dimensionally arranged pixels. Note that since the optical sensor according to the fourth embodiment included in the solid-state image sensor of the seventh embodiment according to the present technology is as described above, description thereof is omitted here.

Since the solid-state image sensor of the seventh embodiment according to the present technology includes the optical sensor of the fourth embodiment according to the present technology having excellent photoelectric conversion efficiency, it is possible to improve the image quality and reliability.

The solid-state image sensor of the seventh embodiment according to the present technology may include the optical sensor of the fourth embodiment for at least one color out of the optical sensor of the fourth embodiment for blue, the optical sensor of the fourth embodiment for green, and the optical sensor of the fourth embodiment for red, or may include the optical sensor of the fourth embodiment for blue, the optical sensor of the fourth embodiment for green, and the optical sensor of the fourth embodiment for red, i.e., the optical sensors of the fourth embodiment for all the above-mentioned three colors.

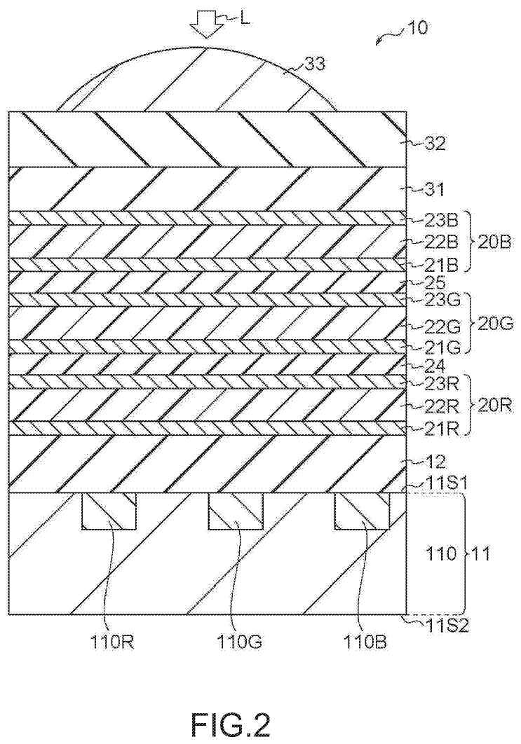

Hereinafter, the solid-state image sensor of the seventh embodiment according to the present technology will be specifically described with reference to FIG. 2. FIG. 2 is a cross-sectional view showing a configuration example of the solid-state image sensor (corresponding to one pixel) of the seventh embodiment according to the present technology. The solid-state image sensor shown in FIG. 2 is an example in which the optical sensor of the fourth embodiment for blue, the optical sensor of the fourth embodiment for green, and the optical sensor of the fourth embodiment for red are used.

A solid-state image sensor (corresponding to one pixel) 10 has, for example, a structure in which a plurality of photoelectric conversion units that selectively detect light having different wavelengths and perform photoelectric conversion is stacked in the thickness direction. Specifically, the solid-state image sensor 10 has, for example, a stacked structure in which a red photoelectric conversion unit 20R, an insulation layer 24, a green photoelectric conversion unit 20G, an insulation layer 25, a blue photoelectric conversion unit 20B, a protective layer 31, and a planarization layer 32 are stacked on a semiconductor substrate 11 in the stated order. An on-chip lens 33 is provided on the planarization layer 32. Since the solid-state image sensor 10 includes the red photoelectric conversion unit 20R, the green photoelectric conversion unit 20G, and the blue photoelectric conversion unit 20B as described above, red (R), green (G), and blue (B) color signals are acquired. Therefore, in the case where the solid-state image sensor 10 is installed, it is possible to a plurality of types of color signals in one pixel without using a color filter as shown in FIG. 2. The red photoelectric conversion unit 20R may include an optical sensor of the fourth embodiment for red, the green photoelectric conversion unit 20G may include an optical sensor of the fourth embodiment for green, and the blue photoelectric conversion unit 20B may include an optical sensor of the fourth embodiment for blue.

The semiconductor substrate 11 is obtained by, for example, embedding a red storage layer 110R, a green storage layer 110G, and a blue storage layer 110B in a predetermined region of a p-type silicon (Si) substrate 110. The red storage layer 110R, the green storage layer 110G, and the blue storage layer 110B each have an n-type semiconductor region. Signal charges (electrons in this embodiment) supplied from the red photoelectric conversion unit 20R, the green photoelectric conversion unit 20G, and the blue photoelectric conversion unit 20B are stored in the n-type semiconductor regions. The n-type semiconductor regions of the red storage layer 110R, the green storage layer 110G, and the blue storage layer 110B are each formed by, for example, doping the semiconductor substrate 11 with an n-type impurity such as phosphorus (P) and arsenic (As).

A conductive plug (not shown) that serves as a transmission path of charges from the photoelectric conversion unit 11G, i.e., electrons or holes, may be embedded in the semiconductor substrate 11. In this embodiment, the back surface (surface 11S1) of the semiconductor substrate 11 is a light reception surface. On the side of the front surface (surface 11S2) of the semiconductor substrate 11, a circuit forming layer in which a peripheral circuit including a logic circuit or the like has been formed is provided in addition to a plurality of pixel transistors corresponding to the red photoelectric conversion unit 20R, the green photoelectric conversion unit 20G, and the blue photoelectric conversion unit 20B (any of which is not shown).

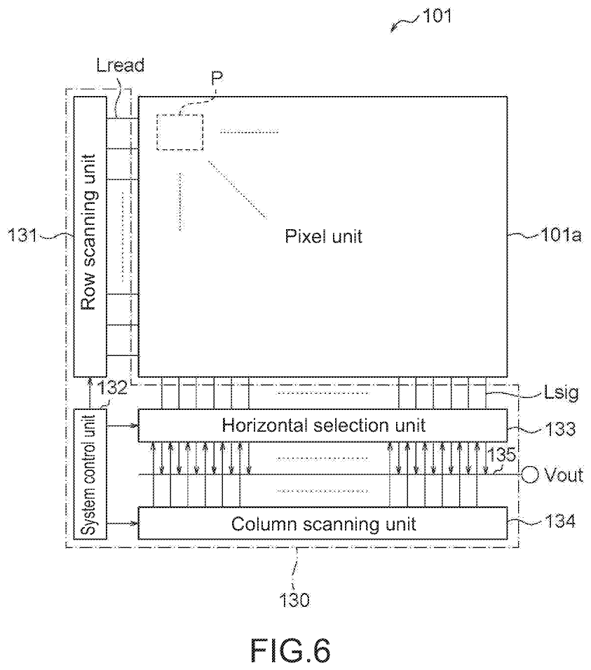

Examples of the pixel transistor include a transfer transistor, a reset transistor, an amplification transistor, and a selection transistor. These pixel transistors each include, for example, a MOS transistor, and is formed in a p-type semiconductor well region on the side of the surface S2. Such a circuit including pixel transistors is formed for each of red, green, and blue photoelectric conversion units. Each circuit may have a three-transistor configuration including the total of three transistors, i.e., a transfer transistor, a reset transistor, and an amplification transistor, for example, out of these pixel transistors, or may have a four-transistor configuration including a selection transistor in addition to the three transistors. The transfer transistor transfers the signal charges corresponding to the respective colors (electrons in this embodiment) that are generated in the red photoelectric conversion unit 20R, the green photoelectric conversion unit 20G, and the blue photoelectric conversion unit 20B and respectively stored in the red storage layer 110R, the green storage layer 110G, and the blue storage layer 110B to a vertical signal line Lsig (see FIG. 6) described below.

An insulation layer 12 on the semiconductor substrate 11 is formed of, for example, silicon oxide (SiO), silicon nitride (SiN), silicon oxynitride (SiON), or hafnium oxide (HfO₂). The insulation layer 12 may be formed by stacking a plurality of types of insulation films. Further, the insulation layer 12 may be formed of an organic insulation material. A plug for connecting the red storage layer 110R and the red photoelectric conversion unit 20R to each other and an electrode (any of which is not shown) are provided in the insulation layer 12. Similarly, a plug and an electrode that connect the green storage layer 110G and the green photoelectric conversion unit 20G to each other, and a plug and an electrode that connect the blue storage layer 110B and the blue photoelectric conversion unit 20B to each other are also provided in the insulation layer 12.

In the red photoelectric conversion unit 20R, a first electrode 21R, a semiconductor film (hereinafter, referred to also simply as a semiconductor film.) 22R according to the first embodiment, and a second electrode 23R are stacked on the insulation layer 12 in the stated order. In the red photoelectric conversion unit 20R, red (e.g., wavelength of 600 nm to 750 nm) light is selectively absorbed and electron-hole pairs are generated. In the green photoelectric conversion unit 20G, a first electrode 21G, a semiconductor film 22G, and a second electrode 23G are stacked on the insulation layer 24 in the stated order. In the green photoelectric conversion unit 20G, green (e.g., wavelength of 500 nm to 650 nm) light is selectively absorbed and electron-hole pairs are generated. In the blue photoelectric conversion unit 20B, a first electrode 21B, a semiconductor film 22B of the first embodiment, and a second electrode 23B are stacked on the insulation layer 25 in the stated order. In the blue photoelectric conversion unit 20B, blue (e.g., wavelength of 400 nm to 550 nm) light is selectively absorbed and electron-hole pairs are generated.

The first electrodes 21R, 21G, and 21B are electrically connected to the above-mentioned conductive plugs embedded in the semiconductor substrate 11. Meanwhile, the second electrodes 23R, 23G, and 23B are connected to the wiring in the above-mentioned circuit forming layer provided on the surface S2 of the semiconductor substrate 11 via a contact portion (not shown) in the peripheral portion of the solid-state image sensor, for example, and thus, charges (here, holes) are discharged.

The semiconductor films 22R, 22G, and 22B are also a photoelectric conversion layer that absorbs light having a selective wavelength, i.e., red light, green light, and blue light, and generates electron-hole pairs.

The first electrodes 21R, 21G, and 21B are provided for each pixel, for example. The first electrodes 21R, 21G, and 21B are each formed of, for example, a conductive material having a light transmission property, specifically, ITO (Indium-Tin-Oxide). The first electrodes 21R, 21G, and 21B may each be formed of, for example, a tin oxide (SnO₂) material or a zinc oxide (ZnO) material. The tin oxide material is one obtained by adding a dopant to tin oxide, and the zinc oxide material is, for example, aluminum zinc oxide (AZO) obtained by adding aluminum (Al) as a dopant to zinc oxide, a gallium zinc oxide (GZO) obtained by adding gallium (Ga) as a dopant to zinc oxide, or an indium zinc oxide (IZO) obtained by adding indium (In) as a dopant to zinc oxide. In addition, IGZO, CuI, InSbO₄, ZnMgO, CuInO₂, MgIn₂O₄, CdO, ZnSnO₃, or the like can be used. The thickness of each of the first electrodes 21R, 21G, and 21B is, for example, 5 nm to 300 nm.

For example, a hole transport layer (not shown) may be provided between the semiconductor film 22R and the second electrode 23R, between the semiconductor film 22G and the second electrode 23G, and between the semiconductor film 22B and the second electrode 23B. This hole transport layer has a function of promoting the supply of holes generated in the semiconductor films 22R, 22G, and 22B to the second electrodes 23R, 23G, and 23B, and is formed of, for example, molybdenum oxide, nickel oxide, or the like. The hole transport layer may be formed by stacking molybdenum oxide and nickel oxide.

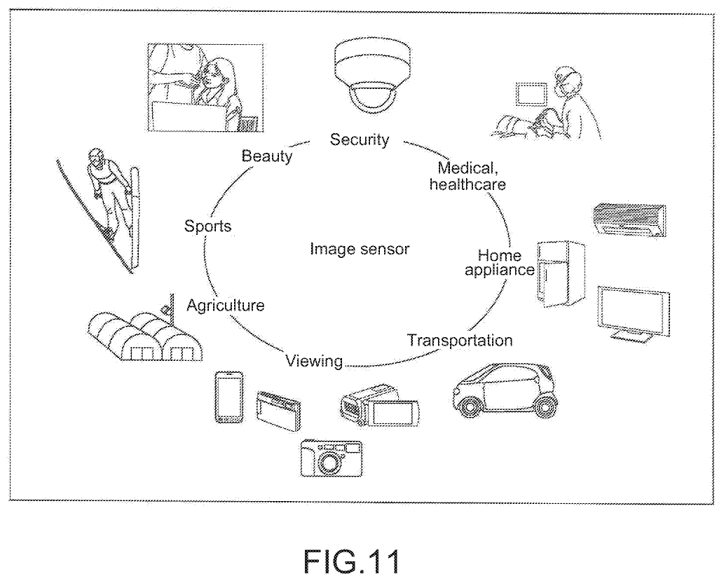

The second electrode 23R, the second electrode 23G, and the second electrode 23B are respectively for taking out holes generated in the semiconductor film 22R, holes generated in the semiconductor film 22G, and holes generated in the semiconductor film 22G. The holes taken out from the second electrodes 23R, 23G, and 23B are discharged to, for example, the p-type semiconductor regions in the semiconductor substrate 11 via respective transmission paths (not shown). Similarly to the first electrodes 21R, 21G, and 21B, also the second electrodes 23R, 23G, and 23B are each formed of a transparent conductive material. In the solid-state image sensor 10, since the holes taken out from the second electrodes 23R, 23G, and 23B are discharged, the second electrodes 23R, 23G, and 23B may be provided commonly to the solid-state image sensor 10 (pixel P in FIG. 11) when the plurality of solid-state image sensors 10 is disposed (for example, the solid-state image sensor 101 in FIG. 6 described below). The thickness of each of the second electrodes 23R, 23G, and 23B is, for example, 5 nm to 300 nm.

The insulation layers 24 and 25 includes a single layer film formed of, for example, one of silicon oxide (SiO), silicon nitride (SiN), silicon oxynitride (SiON), and the like, or a stacked film formed of two or more of them.

The protective layer 31 covering the second electrode 23B is for preventing water and the like from entering the red photoelectric conversion unit 20R, the green photoelectric conversion unit 20G, and the blue photoelectric conversion unit 20B. The protective layer 31 is formed of a material having a light transmission property. As such a protective layer 31, for example, a single layer film formed of silicon nitride, silicon oxide, silicon oxynitride, or the like, or a stacked film formed thereof is used.

The on-chip lens 33 is provided above the protective layer 31 with the planarization layer 32 sandwiched therebetween. As the material of the planarization layer 32, an acrylic resin material, a styrene resin material, an epoxy resin material, or the like can be used. The planarization layer 32 only needs to be provided as necessary, and the protective layer 31 may serve also as the planarization layer 32. The on-chip lens 33 causes the light that has entered from above to be focused on the corresponding light reception surface of the red photoelectric conversion unit 20R, the green photoelectric conversion unit 20G, and the blue photoelectric conversion unit 20B.

(Method of Producing Solid-State Image Sensor 10)

The solid-state image sensor 10 can be produced, for example as follows.

First, the red storage layer 110R, the green storage layer 110G, and the blue storage layer 110B are formed on the semiconductor substrate 11 by, for example, ion implantation. At this time, pixel transistors are also formed on the semiconductor substrate 11. Subsequently, electrodes for electrically connecting the red storage layer 110R, the green storage layer 110G, the blue storage layer 110B and the first electrodes 21R, 21G, and 21B to each other are formed on the semiconductor substrate 11, and then, a silicon oxide film is deposited by, for example, a plasma CVD (Chemical Vapor Deposition) method to form the insulation layer 12. Plugs that reach the electrodes are formed in the insulation layer 12.

Subsequently, the red photoelectric conversion unit 20R, the insulation layer 24, the green photoelectric conversion unit 20G, the insulation layer 25, the blue photoelectric conversion unit 20B, the protective layer 31, and the planarization layer 32 are stacked and formed on the insulation layer 12 in the stated order. Specifically, the first electrode 21R is formed first. The first electrode 21R is formed by depositing an ITO film by, for example, a sputtering method and then patterning this by a photolithography technology and performing dry etching or wet etching.

Subsequently, an electron transport layer formed of, for example, titanium oxide is provided on the first electrode 21R by a sputtering method or the like as necessary, and then, the semiconductor film 22R is formed. The semiconductor film 22R is formed by, for example, coating an ink (semiconductor nanoparticle dispersion) in which a plurality of semiconductor nanoparticles dispersed in a predetermined solvent on the electron transport layer by a spin coat method or the like and then performing heat treatment.

The semiconductor film 22R may have a multi-layer structure in which a large number of thin films of nanoparticles are stacked. Note that the semiconductor film 22R favorably has a film thickness of 500 nm or more for sufficient light absorption, although it depends on the used semiconductor material.

After forming the semiconductor film 22R, a MoO₃ (molybdenum oxide) layer that is a hole transport layer and an Ag (silver) layer that is a reflective electrode are formed by, for example, a vapor deposition method. As this hole transport layer, an organic film of PEDOT (Poly(3,4-ethylenedioxythiophene)), TPD (N,N′-Bis(3-methylphenyl)-N,N′-diphenylbenzidine), or the like in addition to a semiconductor film formed of NiO (nickel oxide) or V₂O₅ may be used.

Subsequently, a conductive film is deposited on this hole transport layer by, for example, a vacuum vapor deposition method to obtain the second electrode 23R. As a result, the red photoelectric conversion unit 20R is formed. Similarly to this, the green photoelectric conversion unit 20G and the blue photoelectric conversion unit 20B are formed.

After forming the blue photoelectric conversion unit 20B, the protective layer 31 is formed on the second electrode 23B of the blue photoelectric conversion unit 20B. After silicon nitride or silicon oxide is deposited by, for example, a plasma CVD method, patterning by a photolithography technology and dry etching are performed, deposits and residues are removed finally by post-treatment such as asking and organic cleaning, and thus, the protective layer 31 is formed.

After forming the protective layer 31, the planarization layer 32 and the on-chip lens 33 are formed on the protective layer 31 in the stated order. Through the above processes, the solid-state image sensor 10 shown in FIG. 2 is completed.

(Operation of Solid-State Image Sensor 10)

In the solid-state image sensor 10, for example, signal charges (electrons) are acquired as pixels of the solid-state image sensor as follows. After light L enters the solid-state image sensor 10, the light L passes through the on-chip lens 33, the blue photoelectric conversion unit 20B, the green photoelectric conversion unit 20G, and the red photoelectric conversion unit 20R in the stated order and is photoelectrically converted for respective colors of blue, green, and red in the course of passage.

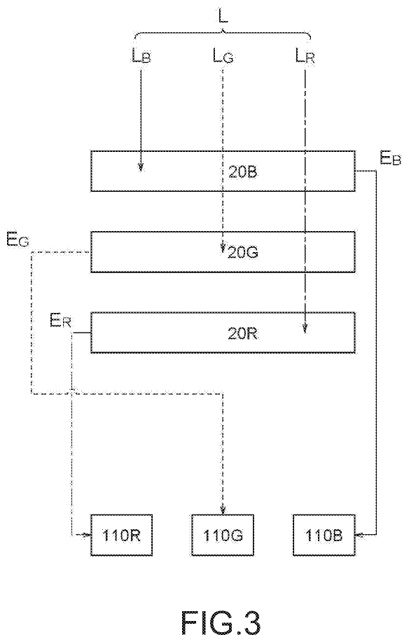

Specifically, as shown in FIG. 3 in detail, of the light L that has entered the solid-state image sensor 10, blue light L_{B} is selectively detected (absorbed) in the blue photoelectric conversion unit 20B first and photoelectrically converted. Of the electron-hole pairs generated in the blue photoelectric conversion unit 20B, electrons E_{B} are taken out from the first electrode 21B and stored in the blue storage layer 110B. Meanwhile, holes are discharged from the second electrode 23B. Similarly, of the light that has been transmitted through the blue photoelectric conversion unit 20B, green light L_{G} is selectively detected in the green photoelectric conversion unit 20G and photoelectrically converted. Of the electron-hole pairs generated in the green photoelectric conversion unit 20G, electrons E_{B} are taken out from the first electrode 21 and stored in the blue storage layer 110B. Of the light that has been transmitted through the blue photoelectric conversion unit 20B and the green photoelectric conversion unit 20G, red light L_{R} is selectively detected in the red photoelectric conversion unit 20R and photoelectrically converted. Of the electron-hole pairs generated in the red photoelectric conversion unit 20R, electrons E_{B} are taken out from the first electrode 21R and stored in the red storage layer 110R.

During the read operation, transfer transistors corresponding to the respective colors are turned on, and the electrons E_{B}, E_{B}, and E_{B} stored in the red storage layer 110R, the green storage layer 110G, and the blue storage layer 110B are transferred to the vertical signal line Lsig (see FIG. 6). As described above, by stacking the blue photoelectric conversion unit 20B, the green photoelectric conversion unit 20G, and the red photoelectric conversion unit 20R in the order in which the light L enters, it is possible to separately detect red, green, and blue light without providing color filters and acquire signal charges of respective colors.

(Modified Example 1)

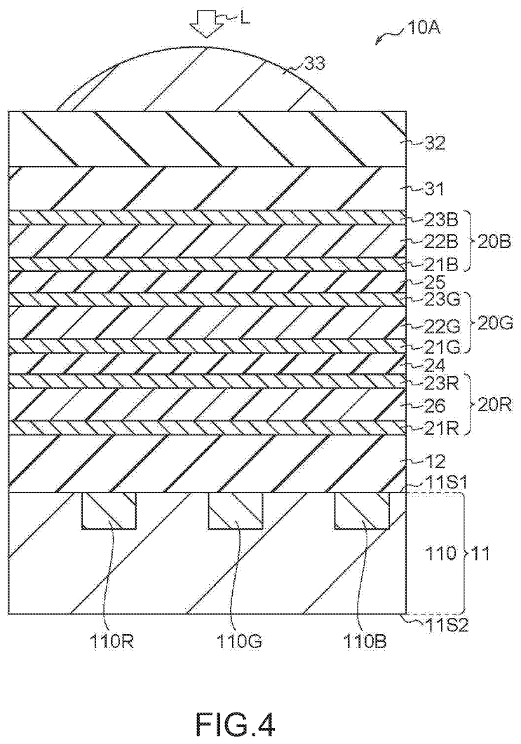

FIG. 4 shows a cross-sectional configuration of a solid-state image sensor (corresponding to one pixel) 10A that is a first modified example of the above-mentioned solid-state image sensor (corresponding to one pixel) 10. Although a semiconductor film is used as a photoelectric conversion film in all of the red photoelectric conversion unit 20R, the green photoelectric conversion unit 20G, and the blue photoelectric conversion unit 20B in the above-mentioned solid-state image sensor 10, the present technology is not limited thereto. As in the solid-state image sensor 10A shown in FIG. 4, for example, a crystalline silicon (Si) layer 26 may be used as a photoelectric conversion film in the red photoelectric conversion unit 20R. In this case, in the crystalline silicon layer 26, red light is selectively absorbed and photoelectrically converted. Even in this case, effects similar to those of the solid-state image sensor 10 can be obtained. Note that an inorganic semiconductor crystal other than crystalline silicon may be used. Further, since the solid-state image sensor 10A uses the crystalline silicon layer 26 instead of the semiconductor film 22R, the configuration of the solid-state image sensor 10A is simpler than the configuration of the solid-state image sensor 10. Therefore, production of the solid-state image sensor 10A is easier than production of the solid-state image sensor 10.

(Modified Example 2)

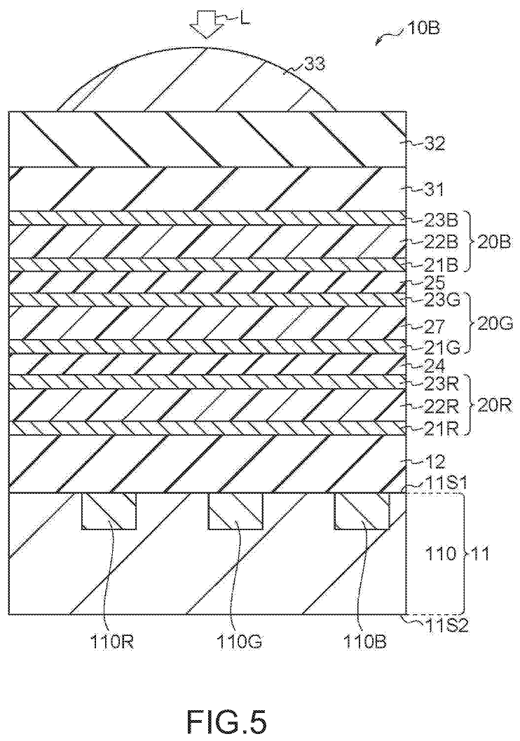

FIG. 5 shows a cross-sectional configuration of a solid-state image sensor (corresponding to one pixel) 10B that is a second modified example of the above-mentioned solid-state image sensor (corresponding to one pixel) 10. The solid-state image sensor 10B has the crystalline silicon layer 26 as the photoelectric conversion film in the red photoelectric conversion unit 20R and an organic semiconductor layer 27 as the photoelectric conversion film in the green photoelectric conversion unit 20G. The organic semiconductor layer 27 is formed of an organic semiconductor that absorbs green light and perform photoelectric conversion while causing light in other wavelength ranges to be transmitted therethrough. Therefore, blue light is selectively absorbed in the nanoparticle layer 22B and photoelectrically converted, green light is selectively absorbed in the organic semiconductor layer 27 and photoelectrically converted, and red light is selectively absorbed in the crystalline silicon layer 26 and photoelectrically converted. Even in this case, effects similar to those of the solid-state image sensor 10 can be obtained.

The organic semiconductor in the organic semiconductor layer 27 is favorably configured to include one of an organic p-type semiconductor and an organic n-type semiconductor or both of them. As such an organic semiconductor, one of a quinacridone derivative, a naphthalene derivative, an anthracene derivative, a phenanthrene derivative, a tetracene derivative, a pyrene derivative, a perylene derivative, and a fluoranthene derivative is favorably used. Alternatively, a polymer such as phenylene vinylene, fluorene, carbazole, indole, pyrene, pyrrole, picoline, thiophene, acetylene, and diacetylene or a derivative thereof may be used. In addition, a metal complex dye, a rhodamine dye, a cyanine dye, a merocyanine dye, a phenylxanthene dye, a triphenylmethane dye, a rhodacyanine dye, a xanthene dye, a macrocyclic azaannulene dye, an azulene dye, a naphthoquinone, an anthraquinone dye, a chain compound in which a fused polycyclic aromatic compound such as anthracene and pyrene and an aromatic ring or a heterocyclic compound are fused, quinoline having a squarylium group and a croconic methine group as a binding chain, two nitrogen-containing heterocycles such as benzothiazole and benzoxazole, a cyanine-like dye linked by a squarylium group and a croconic methine group, or the like is favorably used. Note that as the above-mentioned metal complex dye, a dithiol metal complex dye, a metal phthalocyanine dye, a metal porphyrin dye, or a ruthenium complex dye is favorable, but the present technology is not limited thereto. Further, the solid-state image sensor 10B uses the crystalline silicon layer 26 instead of the semiconductor film 22R and the organic semiconductor layer 27 instead of the semiconductor film 22G. Therefore, the configuration of the solid-state image sensor 10B is simpler than the configuration of the solid-state image sensors 10 or 10A including a plurality of semiconductor films, and production of the solid-state image sensor 10B is relatively easy.

Further, in another modified example, a crystalline silicon layer, a semiconductor film, and an organic semiconductor layer may be respectively used instead or the photoelectric conversion film of the red photoelectric conversion unit 20R, the photoelectric conversion film of the green photoelectric conversion unit 20G, and the photoelectric conversion film of the blue photoelectric conversion unit 20B (modified example 3). Alternatively, a semiconductor film formed of an inorganic semiconductor and an organic semiconductor layer may be respectively used as the photoelectric conversion film of each of the red photoelectric conversion unit 20R and the blue photoelectric conversion unit 20B and the photoelectric conversion film of the green photoelectric conversion unit 20G (modified example 4). Further, an organic semiconductor layer and a semiconductor film may be respectively used as the photoelectric conversion film of each of the red photoelectric conversion unit 20R and the green photoelectric conversion unit 20G and the photoelectric conversion film of the blue photoelectric conversion unit 20G (modified example 5).

Then, the solid-state image sensor of the seventh embodiment according to the present technology may use the optical sensor of the fifth embodiment and/or the optical sensor of the sixth embodiment in combination with the optical sensor of the fourth embodiment.

(Overall configuration of solid-state image sensor)

FIG. 6 is a functional block diagram showing the solid-state image sensor 101. This solid-state image sensor 101 is a CMOS image sensor and includes a pixel unit 101a as an imaging area and a circuit unit 130 including, for example, a row scanning unit 131, a horizontal selection unit 133, a column scanning unit 134, and a system control unit 132. The circuit unit 130 may be provided in the peripheral region of the pixel unit 101a or stacked with the pixel unit 101a (in the region facing the pixel unit 101a).

The pixel unit 101a includes a plurality of unit pixels P (e.g., corresponding to the solid-state image sensors (corresponding to one pixel) 10, 10A, and 10B) that is two-dimensionally disposed in a matrix, for example. In this pixel P, a pixel drive line Lread (specifically, a row selection line and a reset control line) is wired for, for example, each pixel row, and the vertical signal line Lsig is wired for each pixel column. The pixel drive line Lread is for transmitting a drive signal for reading a signal from a pixel. One end of the pixel drive line Lread is connected to the output end corresponding to each row of the row scanning unit 131.

The row scanning unit 131 is a pixel drive unit that includes a shift resister, an address decoder, and the like and drives each of pixels P of the pixel unit 101a in, for example, a row unit. The signals output from the pixels P in the pixel row selectively scanned by the row scanning unit 131 are supplied to the horizontal selection unit 133 through the corresponding vertical signal line Lsig. The horizontal selection unit 133 includes amplifier, a horizontal selection switch, and the like provided for each of the vertical signal lines Lsig.

The column scanning unit 134 includes a shift resister, an address decoder, and the like, and drives the horizontal selection switches of the horizontal selection unit 133 in order while scanning them. By this selective scanning by the column scanning unit 134, the signal of each pixel transmitted through the corresponding vertical signal line Lsig is sequentially transmitted to a horizontal signal line 135 and output to the outside through the horizontal signal line 135.

The system control unit 132 receives an externally supplied clock, data instructing an operation mode, and the like, and outputs data such as internal information of the solid-state image sensor 101. The system control unit 132 further includes a timing generator that generates various timing signals, and performs drive control of the row scanning unit 131, the horizontal selection unit 133, and the column scanning unit 134 on the basis of various timing signals generated by the timing generator.

### 9. Eighth Embodiment (Example 2 of Solid-State Image Sensor)

A solid-state image sensor of an eighth embodiment of the present technology (example 2 of solid-state image sensor) is a solid-state image sensor including: at least an optical sensor of the fifth embodiment according to the present technology and a semiconductor substrate stacked for each of a plurality of one- or two-dimensionally arranged pixels. Note that since the optical sensor of the fifth embodiment included in the solid-state image sensor of the eighth embodiment according to the present technology is as described above, description thereof is omitted here.

Since the solid-state image sensor of the eighth embodiment according to the present technology includes the optical sensor of the fifth embodiment according to the present technology having excellent photoelectric conversion efficiency, it is possible to improve the image quality and reliability.

The solid-state image sensor of the eighth embodiment according to the present technology may include at least the optical sensor of the fifth embodiment for at least one color of the optical sensor out of the fifth embodiment for blue, the optical sensor of the fifth embodiment for green, and the optical sensor of the fifth embodiment for red, or may include the optical sensor of the fifth embodiment for blue, the optical sensor of the fifth embodiment for green, and the optical sensor of the fifth embodiment for red, i.e., the optical sensors of the fifth embodiment for all the above-mentioned three colors.

Since the configuration of the solid-state image sensor of the eighth embodiment according to the present technology is similar to the configuration of the solid-state image sensor of the seventh embodiment according to the present technology, the content of FIG. 2 to FIG. 6 described in the column of the solid-state image sensor of the seventh embodiment according to the present technology and the content of the modified examples 3 to 5 are applicable to the solid-state image sensor of the eighth embodiment according to the present technology.

Further, similarly to the solid-state image sensor of the seventh embodiment according to the present technology, the solid-state image sensor of the eighth embodiment according to the present technology may use the optical sensor of the fourth embodiment and/or the optical sensor of the sixth embodiment in combination with the optical sensor of the fifth embodiment.

### 10. Ninth Embodiment (Example 3 of Solid-State Image Sensor)

A solid-state image sensor of a ninth embodiment according to the present technology (example 3 of solid-state image sensor) is a solid-state image sensor including: at least the optical sensor of the sixth embodiment according to the present technology and a semiconductor substrate stacked for each of a plurality of one- or two-dimensionally arranged pixels. Note that since the optical sensor of the sixth embodiment included in the solid-state image sensor of the ninth embodiment according to the present technology is described above, description thereof is omitted here.

Since the solid-state image sensor of the ninth embodiment according to the present technology includes the optical sensor of the sixth embodiment according to the present technology having excellent photoelectric conversion efficiency, it is possible to improve the image quality and reliability.

The solid-state image sensor of the ninth embodiment according to the present technology may include the optical sensor of the sixth embodiment for at least one color out of the optical sensor of the sixth embodiment for blue, the optical sensor of the sixth embodiment for green, and the optical sensor of the sixth embodiment for red, or may include the optical sensor of the sixth embodiment for blue, the optical sensor of the sixth embodiment for green, and the optical sensor of the sixth embodiment for red, i.e., the optical sensors of the sixth embodiments for all the above-mentioned three colors.

Since the configuration of the solid-state image sensor of the ninth embodiment according to the present technology is similar to the configuration of the solid-state image sensor of the seventh embodiment according to the present technology, the content of FIG. 2 to FIG. 6 described in the column of the solid-state image sensor of the seventh embodiment according to the present technology and the content of the modified examples 3 to 5 are applicable to the solid-state image sensor of the ninth embodiment according to the present technology.

Further, similarly to the solid-state image sensor of the seventh embodiment according to the present technology, the solid-state image sensor of the ninth embodiment according to the present technology may use the optical sensor of the fourth embodiment and/or the optical sensor of the fifth embodiment in combination with the optical sensor of the sixth embodiment.

### 11. Tenth Embodiment (Example 1 of Solar Battery)

A solar battery of a tenth embodiment according to the present technology (example 1 of solar battery) is a solar battery including: at least the semiconductor film of the first embodiment according to the present technology; and a first electrode and a second electrode that are disposed to face each other, in which the semiconductor film is disposed between the first electrode and the second electrode. Note that since the semiconductor film of the first embodiment included in the solar battery of the tenth embodiment according to the present technology is as described above, description thereof is omitted here.

Since the solar battery of the tenth embodiment according to the present technology includes the semiconductor film of the first embodiment according to the present technology, which efficiently absorbs a specific wavelength range and has excellent photoelectric conversion efficiency, it is possible to convert sunlight energy having a wide wavelength distribution into electric energy with high efficiency, and improve the battery characteristics as a result thereof.

The solar battery of the tenth embodiment according to the present technology may be a multi-junction (tandem, stack, or stacked) solar battery. Examples of the multi-junction solar battery include a two-junction solar battery, a three-junction solar battery, a four-junction solar battery, and a six-junction solar battery. Further, the multi-junction solar battery of the tenth embodiment according to the present technology may be a multi-junction solar battery obtained by, for example, stacking a plurality of sub-cells in which a plurality of semiconductor films of the first embodiment is stacked, an amorphous connection layer formed of a conducive material being provided in at least one location between the adjacent sub-cells.

The multi-junction solar battery of the tenth embodiment according to the present technology may include, as the semiconductor film of the first embodiment, at least one of the semiconductor film of the first embodiment absorbing light of a short wavelength range (e.g., blue light), the semiconductor film of the first embodiment absorbing light of a medium wavelength range (e.g., green light), and the semiconductor film of the first embodiment absorbing light of a long wavelength range (e.g., red light), or may include, as the semiconductor film of the first embodiment, all of the semiconductor film of the first embodiment absorbing light of a short wavelength range (e.g., blue light), the semiconductor film of the first embodiment absorbing light of a medium wavelength range (e.g., green light), and the semiconductor film of the first embodiment absorbing light of a long wavelength range (e.g., red light).

Note that in the solar battery of the tenth embodiment according to the present technology, the semiconductor film of the first embodiment and the semiconductor film of the second embodiment may be used in combination, the semiconductor film of the first embodiment and the semiconductor film of the third embodiment may be used in combination, or the semiconductor film of the first embodiment, the semiconductor film of the second embodiment, and the semiconductor film of the third embodiment may be used in combination.

### 12. Eleventh Embodiment (Example 2 of Solar Battery)

A solar battery of a eleventh embodiment according to the present technology (example 2 of solar battery) is a solar battery including: at least the semiconductor film of the second embodiment according to the present technology; and a first electrode and a second electrode that are disposed to face each other, in which the semiconductor film is disposed between the first electrode and the second electrode. Note that since the semiconductor film of the second embodiment included in the solar battery of the eleventh embodiment according to the present technology is as described above, description thereof is omitted here.

Since the solar battery of the eleventh embodiment according to the present technology includes the semiconductor film of the second embodiment according to the present technology, which efficiently absorbs a specific wavelength range and has excellent photoelectric conversion efficiency, it is possible to convert sunlight energy having a wide wavelength distribution into electric energy with high efficiency, and improve the battery characteristics as a result thereof.

The solar battery of the eleventh embodiment according to the present technology may be a multi-junction (tandem, stack, or stacked) solar battery. Examples of the multi-junction solar battery include a two-junction solar battery, a three-junction solar battery, a four-junction solar battery, and a six-junction solar battery. Further, the multi-junction solar battery of the eleventh embodiment according to the present technology may be a multi-junction solar battery obtained by, for example, stacking a plurality of sub-cells in which a plurality of semiconductor films of the second embodiment is stacked, an amorphous connection layer formed of a conducive material being provided in at least one location between the adjacent sub-cells.

The multi-junction solar battery of the tenth embodiment according to the present technology may include, as the semiconductor film of the second embodiment, at least one of the semiconductor film of the second embodiment absorbing light of a short wavelength range (e.g., blue light), the semiconductor film of the second embodiment absorbing light of a medium wavelength range (e.g., green light), and the semiconductor film of the second embodiment absorbing light of a long wavelength range (e.g., red light), or may include, as the semiconductor film of the second embodiment, all of the semiconductor film of the second embodiment absorbing light of a short wavelength range (e.g., blue light), the semiconductor film of the second embodiment absorbing light of a medium wavelength range (e.g., green light), and the semiconductor film of the second embodiment absorbing light of a long wavelength range (e.g., red light).

Note that in the solar battery of the eleventh embodiment according to the present technology, the semiconductor film of the second embodiment and the semiconductor film of the first embodiment may be used in combination, the semiconductor film of the second embodiment and the semiconductor film of the third embodiment may be used in combination, or the semiconductor film of the second embodiment, the semiconductor film of the first embodiment, and the semiconductor film of the third embodiment may be used in combination.

### 13. Twelfth Embodiment (Example 3 of Solar Battery)

A solar battery of a twelfth embodiment according to the present technology (example 3 of solar battery) is a solar battery including: at least the semiconductor film of the third embodiment according to the present technology; and a first electrode and a second electrode that are disposed to face each other, in which the semiconductor film is disposed between the first electrode and the second electrode. Note that since the semiconductor film of the third embodiment included in the solar battery of the twelfth embodiment according to the present technology is as described above, description thereof is omitted here.

Since the solar battery of the twelfth embodiment according to the present technology includes the semiconductor film of the third embodiment according to the present technology, which efficiently absorbs a specific wavelength range and has excellent photoelectric conversion efficiency, it is possible to convert sunlight energy having a wide wavelength distribution into electric energy with high efficiency, and improve the battery characteristics as a result thereof.

The solar battery of the twelfth embodiment according to the present technology may be a multi-junction (tandem, stack, or stacked) solar battery. Examples of the multi-junction solar battery include a two-junction solar battery, a three-junction solar battery, a four-junction solar battery, and a six-junction solar battery. Further, the multi-junction solar battery of the twelfth embodiment according to the present technology may be a multi-junction solar battery obtained by, for example, stacking a plurality of sub-cells in which a plurality of semiconductor films of the third embodiment is stacked, an amorphous connection layer formed of a conducive material being provided in at least one location between the adjacent sub-cells.

The multi-junction solar battery of the twelfth embodiment according to the present technology may include, as the semiconductor film of the third embodiment, at least one of the semiconductor film of the third embodiment absorbing light of a short wavelength range (e.g., blue light), the semiconductor film of the third embodiment absorbing light of a medium wavelength range (e.g., green light), and the semiconductor film of the third embodiment absorbing light of a long wavelength range (e.g., red light), or may include, as the semiconductor film of the third embodiment, all of the semiconductor film of the third embodiment absorbing light of a short wavelength range (e.g., blue light), the semiconductor film of the third embodiment absorbing light of a medium wavelength range (e.g., green light), and the semiconductor film of the third embodiment absorbing light of a long wavelength range (e.g., red light).

Note that in the solar battery of the twelfth embodiment according to the present technology, the semiconductor film of the third embodiment and the semiconductor film of the first embodiment may be used in combination, the semiconductor film of the third embodiment and the semiconductor film of the second embodiment may be used in combination, or the semiconductor film of the third embodiment, the semiconductor film of the first embodiment, and the semiconductor film of the second embodiment may be used in combination.

### 14. Thirteenth Embodiment (Example of Electronic Apparatus)

An electronic apparatus of a thirteenth embodiment of the present technology is an electronic apparatus including: the solid-state image sensor of at least one embodiment of the seventh to ninth embodiments according to the present technology. Since the solid-state image sensors of the seventh to ninth embodiments according to the present technology are as described above, description thereof is omitted here. Since the electronic apparatus of the thirteenth embodiment according to the present technology includes the solid-state image sensor having excellent photoelectric conversion efficiency, it is possible to improve performance such as image quality of a color image.

### 15. Usage Example of Solid-State Image Sensor to which Present Technology is Applied

FIG. 11 is a diagram showing a usage example of the solid-state image sensors of the seventh to ninth embodiments according to the present technology as image sensors.

The above-mentioned solid-state image sensors of the seventh to ninth embodiments can be used in various cases for sensing light such as visible light, infrared light, ultraviolet light, and X-rays, for example, as described below. That is, as shown in FIG. 11, for example, the solid-state image sensor of one embodiment of the seventh to ninth embodiments can be used for the apparatus (e.g., the above-mentioned electronic apparatus of the thirteenth embodiment) used in the field of viewing in which an image used for viewing is taken, the field of transportation, the field of home appliance, the field of medical healthcare, the field of security, the field of beauty, the field of sports, the field of agriculture, and the like.

Specifically, in the field of viewing, for example, the solid-state image sensor of one embodiment of the seventh to ninth embodiments can be used for the apparatus that takes an image used for viewing, such as a digital camera, a smartphone, a mobile phone with a camera function.

In the field of transportation, for example, the solid-state image sensor of one embodiment of the seventh to ninth embodiments can be used for the apparatus used for transportation, such as an in-vehicle sensor that images the front, rear, surroundings, inside, and the like of an automobile for safe driving such as automatic stop, recognition of the driver's condition, and the like, a surveillance camera that monitors running vehicles and roads, and a distance sensor for distance measurement between vehicles.

In the field of home appliance, for example, the solid-state image sensor of one embodiment of the seventh to ninth embodiments can be used for the apparatus used for home appliance such as a television receiver, a refrigerator, and an air conditioner for imaging gesture of a user and performing the device operation according to the gesture.

In the field of medical healthcare, for example, the solid-state image sensor of one embodiment of the seventh to ninth embodiments can be used for the apparatus used for medical and health care, such as an endoscope and an apparatus that takes angiography by receiving infrared light.

In the field of security, for example, the solid-state image sensor of one embodiment of the seventh to ninth embodiments can be used for the apparatus used for security, such as a security camera for crime prevention and a camera for person authentication.

In the field of beauty, for example, the solid-state image sensor of one embodiment of the seventh to ninth embodiments can be used for the apparatus used for beauty, such as a skin measuring device that images skin and a microscope that images a scalp.

In the field of sports, for example, the solid-state image sensor of one embodiment of the seventh to ninth embodiments can be used for the apparatus used for sports, such as an action camera and a wearable camera for sports applications.

In the field of agriculture, for example, the solid-state image sensor of one embodiment of the seventh to ninth embodiments can be used for the apparatus used for agriculture, such as a camera for monitoring the condition of fields and crops.

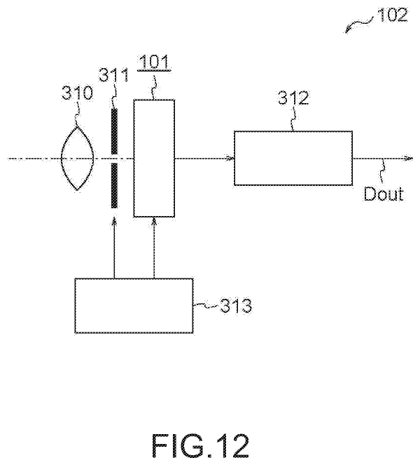

Next, the usage example of the solid-state image of the seventh to ninth embodiments according to the present technology will be specifically described. For example, the solid-state image sensor 101 described above is applicable to, for example, all types of electronic apparatuses with an imaging function, such as a camera system such as a digital still camera and a video camera, and a mobile phone with an imaging function. FIG. 12 shows a schematic configuration of an electronic apparatus 102 (camera) as an example thereof. This electronic apparatus 102 is , for example, a video camera capable of imaging a still image or a moving image, and includes the solid-state image sensor 101, an optical system (optical lens) 310, a shutter device 311, the solid-state image sensor 101, a drive unit 313 that drives the shutter device 311, and a signal processing unit 312.

The optical system 310 guides image light (incident light) from an object to the pixel unit of the solid-state image sensor 101. This optical system 310 may include a plurality of optical lenses. The shutter device 311 is for controlling the light irradiation period and light shielding period for the solid-state image sensor 101. The drive unit 313 is for controlling the transfer operation of the solid-state image sensor 101 and the shutter operation of the shutter device 311. The signal processing unit 312 is for performing various types of signal processing on the signal output from the solid-state image sensor 101. A video signal Dout after the signal processing is stored in a storage medium such as a memory or output to a monitor or the like.

### EXAMPLE

Hereinafter, the effects of the present technology will be specifically described with reference to Examples. Note that the scope of the present technology is not limited to the Examples.

### Example 1

### Synthesis Method 1 of Sulfur-Coordinated Semiconductor Nanoparticles

Hereinafter, a synthesis method 1 of sulfur-coordinated semiconductor nanoparticles 1 (a core portion: ZnCuInS₃, a shell portion: ZnS) will be shown.

(Synthesis of ZnCuInS₃ Nanoparticles)

Zinc acetate 183.5 mg (1 mmol), indium acetate 292.0 mg (1 mmol), copper acetate 181.6 mg (1 mmol), 1-dodecanethiol 4.8 ml, and a 1-octadecene solution 30 ml of oleic acid 1.9 ml were added to a 50 ml three-necked flask, the pressure was reduced using a vacuum pump, and purging with argon was repeated three times. After the temperature inside the flask was raised to 230° C. under an argon atmosphere, an oleylamine solution 5 ml of sulfur 96.2 mg (3 mmol) prepared in advance was quickly added thereto and stirred for 10 minutes. After naturally cooling the reaction solution to room temperature, the reaction solution the reaction solution was evenly added to two 50 ml centrifuge tubes, hexane 10 ml and ethanol 25 ml were added to the respective centrifuge tubes, centrifugation was performed at room temperature and 7700 G for 10 min, and the supernatant was removed. After the precipitate was redispersed with hexane 10 ml, ethanol 35 ml was added thereto and centrifugation was performed at room temperature and 7700 G. After repeating this two times, vacuum drying was performed overnight.

(Synthesis of 1-dodecanethiol-Coordinated Semiconductor Nanoparticles 1 (a Core Portion: ZnCuInS₃, a Shell Portion: ZnS))

ZnCuInS₃ nanoparticles 800 mg, 1-dodecanethiol 6 ml, and 1-octadecene 12 ml were added to a 50 ml flask, and vacuum deaeration was performed at 120° C. for 30 min. After that, the temperature was raised to 230° C. under an argon atmosphere.

Meanwhile, zinc acetate 2.112 g (11.5 mmol), oleylamine 6 ml, and 1-octadecene 14 ml were added to another 50 ml two-necked flasks, the pressure was reduced using a vacuum pump, purging with argon was repeated three time, and then, the temperature was raised to 150° C. and the prepared solution 12 ml was added thereto and stirred at 230° C. for 30 minutes. After naturally cooling the reaction solution to room temperature, the reaction solution was evenly added to two 50 ml centrifuge tubes, hexane 10 ml and ethanol 20 ml were added to the respective centrifuge tubes, centrifugation was performed at room temperature and 7700 G for 10 min, and the supernatant was removed. After the precipitate was redispersed with hexane 10 ml, ethanol 35 ml was added thereto, and centrifugation was performed at room temperature and 7700 G. After repeating this two times, vacuum drying was performed overnight.

(Ligand Exchange from 1-dodecanethiol to Sulfur (S) Ligand)

1-dodecanethiol-coordinated semiconductor nanoparticles 1 (a core portion: ZnCuInS₃, a shell portion: ZnS) 200 mg were measured in a 50 ml centrifuge tube, and chloroform 2 ml was added thereto and dissolved. N,N-dimethylformamide 4 ml was added thereto and mixed, and then, a 30% ammonium sulfide aqueous solution 2 ml was added thereto and stirred. After hexane 40 ml was added thereto and mixed, centrifugation was performed at room temperature and 7700 G and the supernatant was removed. The obtained precipitate was redispersed with N,N-dimethylformamide.

### Example 2

### Synthesis Method 2 of Sulfur-Coordinated Semiconductor Nanoparticles

Hereinafter, a synthesis method 2 of sulfur-coordinated semiconductor nanoparticles 2 (ZnCuInSe₃) will be shown.

(Preparation of Zn Stock Solution)

Zinc acetate (18.3 mg, 0.1 mmol), oleylamine (0.2 ml), and 1-octadecene (0.8 ml) were added to a 50 ml two-necked flask, and vacuum deaeration was performed at 120° C. for 30 min. After that, the temperature was raised to 150° C. under an argon atmosphere, and zinc acetate was dissolved to prepare Zn Stock Solution.

(Preparation of DPP-Se Solution)

Selenium powder (0.024 g, 0.3 mmol) and oleylamine (0.5 ml) were added to a 50 ml two-necked flask, and vacuum deaeration was performed for 30 min. Diphenylphosphine (0.3 ml) was added thereto and stirred under an argon atmosphere, and selenium was dissolved to prepare a DPP-Se solution.

(Synthesis of ZnCuInSe₃)

Coper iodide (9.0 mg, 0.1 mmol), indium acetate (29.0 mg, 0.1 mmol), oleylamine (2.0 ml), and 1-octadecene (1.5 ml) were added to a 50 ml three-necked flask, and vacuum deaeration was performed at 120° C. for 30 min. After that, a Zn Stock solution (1 ml) was added thereto and heated to 200° C. under an argon atmosphere. DPP-Se was quickly added thereto, and stirred for 5 min. After naturally cooling the reaction solution to room temperature, the reaction solution was evenly added to two 50 ml centrifuge tubes, and hexane 10 ml and ethanol 20 ml were added to the respective centrifuge tubes, centrifugation was performed at room temperature and 7700 G for 10 min, and the supernatant was removed. After the precipitate was redispersed with hexane 10 ml, ethanol 35 ml was added thereto, and centrifugation was performed at room temperature and 7700 G. After repeating this two times, vacuum drying was performed overnight.

### Example 3

### Synthesis Method 3 of Sulfur-Coordinated Semiconductor Nanoparticles

Hereinafter, a synthesis method 3 of sulfur-coordinated semiconductor nanoparticles 3 (a core portion: ZnCuInS₃, a shell portion: ZnS) will be shown.

(Preparation of Cu Stock Solution)

Copper acetate 544.9 mg (3 mmol), oleic acid 1.5 ml, and 1-octadecene 13.5 ml were added to a 50 ml three-necked flask, the pressure was reduced using a vacuum pump, and purging with argon was repeated three times. The temperature inside the flask was raised to 160° C. under an argon atmosphere and then kept for 10 minutes, and copper acetate was dissolved to obtain a clear deep blue solution. This solution was naturally cooled to 50° C. and preserved at 50° C.

(Preparation of In stock solution)

Indium acetate 875.8 mg (3 mmol), oleic acid 3 ml, and 1-octadecene 12 ml were added to a 50 ml three-necked flask, the pressure was reduced using a vacuum pump, and purging with argon was repeated three times. The temperature inside the flask was raised to 200° C. under an argon atmosphere and then kept for 10 minutes, and indium acetate was dissolved to obtain a colorless transparent solution. This solution was naturally cooled to 50° C. and preserved at 50° C.

(Preparation of Zn Stock Solution)

Zinc acetate 733.9 mg (4 mmol), oleylamine 3 ml, and 1-octadecene 10 ml were added to a 50 ml three-necked flask, the pressure was reduced using a vacuum pump, and purging with argon was repeated three times. The temperature inside the flask was raised to 160° C. under an argon atmosphere and then kept for 10 minutes, and indium acetate was dissolved to obtained a colorless transparent solution. This solution was naturally cooled to 50° C. and preserved at 50° C.

(Synthesis of ZnCuInS₃)

The pressure inside a 100 ml three-necked flask was reduced using a vacuum pump, purging with argon was repeated three times to make an argon atmosphere. A Cu stock solution 10 ml, an In stock solution 10 ml, a Zn stock solution 2.5 ml, 1-dodecanethiol 10 ml, and 1-octadecene 30 ml were added thereto, and the temperature was raised to 230° C. A 1-octadecene solution 8 ml of S 96.2 mg (3 mmol) prepared in advance was added thereto at 230° C. and stirred for 10 minutes. After naturally cooling the reaction solution to room temperature, the reaction solution was evenly added to two 50 ml centrifuge tubes, hexane 10 ml and ethanol 25 ml were added to the respective centrifuge tubes, centrifugation was performed at room temperature and 7700 G for 10 min, and the supernatant was removed. After the precipitate was redispersed with hexane 10 ml, ethanol 35 ml was added thereto and centrifugation was performed at room temperature and 7700 G. After repeating this two times, vacuum drying was performed overnight.

(Synthesis of 1-dodecanethiol-Coordinated Semiconductor Nanoparticles 3 (a Core Portion: ZnCuInS₃, a Shell Portion: ZnS))

ZnCuInS3 nanoparticles 800 mg, 1-dodecanethiol 6 ml, and 1-octadecene 12 ml were added to a 50 ml flask, and vacuum deaeration was performed at 120° C. for 30 min. After that, the temperature was raised at 230° C. under an argon atmosphere. Meanwhile, zinc acetate 2.112 g (1.5 mmol), oleylamine 6 ml, and 1-octadecene 14 ml were added to another 50 ml two-necked flask, the pressure was reduced using a vacuum pump, purging with argon was repeated three times, and then, the temperature was raised to 150° C. and the prepared solution 12 ml was added thereto and stirred at 230° C. for 30 minutes. After naturally cooling the reaction solution to room temperature, the reaction solution was evenly added to two 50 ml centrifuge tubes, hexane 10 ml and ethanol 20 ml were added to the respective centrifuge tubes, centrifugation was performed at room temperature and 7700 G for 10 min, and the supernatant was removed. After the precipitate was redispersed with hexane 10 ml, ethanol 35 ml was added thereto, and centrifugation was performed at room temperature and 7700 G. After repeating this two times, vacuum drying was performed overnight.

(Ligand Exchange from 1-dodecanethiol to Sulfur (S) Ligand)

The 1-dodecanethiol-coordinated semiconductor nanoparticles 3 (a core portion:ZnCuInS₃, a shell portion: ZnS) 200 mg were measured in a 50 ml centrifuge tube, and chloroform 2 ml was added thereto and dissolved. After N,N-dimethylformamide 4 ml was added thereto and mixed, a 30% ammonium sulfide aqueous solution 2 ml was added thereto and stirred. Hexane 40 ml was added thereto and mixed, and then, centrifugation was performed at room temperature and 7700 G, and the supernatant was removed. The obtained precipitate was redispersed with N,N-dimethylformamide.

### Example 4

### Synthesis Method 4 of Sulfur-Coordinated Semiconductor Nanoparticles

Hereinafter, a synthesis method 4 of sulfur-coordinated semiconductor nanoparticles 4 (a core portion: ZnCuInSe₃, a shell portion: ZnS) will be shown.

(Preparation of Cu Stock Solution)

Copper acetate 544.9 mg (3 mmol), oleic acid 1.5 ml, and 1-octadecene 13.5 ml were added to a 50 ml three-necked flask, the pressure was reduced using a vacuum pump, and purging with argon was repeated three times. The temperature inside the flask was raised to 160° C. under an argon atmosphere and then kept for 10 minutes, and copper acetate was dissolved to obtain a clear deep blue solution. This solution was naturally cooled to 50° C. and preserved at 50° C.

(Preparation of In Stock Solution)

Indium acetate 875.8 mg (3 mmol), oleic acid 3 ml, and 1-octadecene 12 ml were added to a 50 ml three-necked flask, the pressure was reduced using a vacuum pump, and purging with argon was repeated three times. The temperature inside the flask was raised to 200° C. under an argon atmosphere and then kept for 10 minutes, and indium acetate was dissolved to obtain a colorless transparent solution. This solution was naturally cooled to 50° C. and preserved at 50° C.

(Preparation of Zn Stock Solution)

Zinc acetate 733.9 mg (4 mmol), oleylamine 3 ml, and 1-octadecene 10 ml were added to a 50 ml three-necked flask, the pressure was reduced using a vacuum pump, and purging with argon was repeated three times. The temperature inside the flask was raised to 160° C. under an argon atmosphere and then kept for 10 minutes, and indium acetate was dissolved to obtain a colorless transparent solution. This solution was naturally cooled to 50° C. and preserved at 50° C.

(Synthesis of ZnCuInSe₃)

The pressure inside a 100 ml three-necked flask was reduced using a vacuum pump, purging with argon was repeated three times to make an argon atmosphere. A Cu stock solution 10 ml, an In stock solution 10 ml, a Zn stock solution 2.5 ml, 1-dodecanethiol 10 ml, and 1-octadecene 30 ml were added thereto, and the temperature was raised to 230° C. A mixed solution of oleylamine 2.25 ml and 1-dodecanethiol 0.75 ml containing selenium 236.88 mg (3 mmol), which was prepared in advance, was added thereto at 230° C. and stirred for 10 minutes. After naturally cooling the reaction solution to room temperature, the reaction solution was evenly added to two 50 ml centrifuge tubes, hexane 10 ml and ethanol 25 ml were added to the respective centrifuge tubes, centrifugation was performed at room temperature and 7700 G for 10 min, and the supernatant was removed. After the precipitate was redispersed with hexane 10 ml, ethanol 35 ml was added thereto and centrifugation was performed at room temperature and 7700 G. After repeating this two times, vacuum drying was performed overnight.

(Synthesis of 1-dodecanethiol-Coodinated Semiconductor Nanoparticles 4 (a Core Portion: ZnCuInSe₃, a Shell Portion: ZnS))

ZnCuInSe₃ nanoparticles 800 mg, 1-dodecanethiol 6 ml, and 1-octadecene 12 ml were added to a 50 ml flask, and vacuum deaeration was performed at 120° C. for 30 min. After that, the temperature was raised to 230° C. under an argon atmosphere. Meanwhile, zinc acetate 2.112 g (1.5 mmol), oleylamine 6 ml, and 1-octadecene 14 ml were added to another 50 ml two-necked flask, the pressure was reduced using a vacuum pump, purging with argon was repeated three times, and then, the temperature was raised to 150° C. and the prepared solution 12 ml was added thereto and stirred at 230° C. for 30 minutes. After naturally cooling the reaction solution to room temperature, the reaction solution was evenly added to two 50 ml centrifuge tubes, hexane 10 ml and ethanol 20 ml were added to the respective centrifuge tubes, centrifugation was performed at room temperature and 7700 G for 10 min, and the supernatant was removed. After the precipitate was redispersed with hexane 10 ml, ethanol 35 ml was added thereto, and centrifugation was performed at room temperature and 7700 G. After repeating this two times, vacuum drying was performed overnight.

(Ligand Exchange from 1-dodecanethiol to Sulfur (S) Ligand)

The 1-dodecanethiol-coordinated semiconductor nanoparticles (a core portion: ZnCuInSe₃, a shell portion: ZnS) 200 mg was measured in a 50 ml centrifuge tube, and chloroform 2 ml was added thereto and dissolved. N,N-dimethylformamide 4 ml was added thereto and mixed, and then, a 30% ammonium sulfide aqueous solution 2 ml was added there to and stirred. Hexane 40 ml was added thereto and mixed, and then, centrifugation was performed at room temperature and 7700 G, and the supernatant was removed. Th obtained precipitate was redispersed with N,N-dimethylformamide, and then, gel filtration (Bio-Beads X1 Support as the gel, N,N-dimethylformamide as the solvent) was performed to obtain sulfur (S)-coordinated semiconductor nanoparticles 4 (a core portion: ZnCuInSe₃, a shell portion: ZnS).

### Example 5

### Preparation of Dispersion Liquid 1

Example 5 is an example relating to preparation of a dispersion liquid 1 used for preparing a semiconductor film containing semiconductor nanoparticles in an optical sensor using semiconductor nanoparticles. That is, Example 5 is an example in which a dispersion liquid of semiconductor nanoparticles of sulfur-coordinated Znₓ₂CU_{y3}In_{z3}S_{(2x2+y3+3z3)/2} is prepared.

First, 1-dodecanethiol-coordinated Znₓ₂CU_{y3}In_{z3}S_{(2x2+y3+3z3)/2} quantum dots (semiconductor nanoparticles) 0.1 g were dispersed in chloroform 1 ml and dimethyl sulfoxide 2 ml is added thereto. A 48% ammonium sulfide aqueous solution 0.1 ml was added thereto and stirred for one minute. A mixed solution of acetone/hexane=1/1 is added thereto and centrifugation is performed. The supernatant was removed and the precipitate was dispersed in dimethylformamide to obtain a dimethylformamide dispersion liquid of sulfur-coordinated Znₓ₂CU_{y3}In_{z3}S_{(2x2+y3+3z3)/2} quantum dots.

### Example 6

### Preparation of Optical Sensor

Example 6 is an example relating to preparation of an optical sensor using the dispersion liquid 1 used for preparing a semiconductor film containing semiconductor nanoparticles.

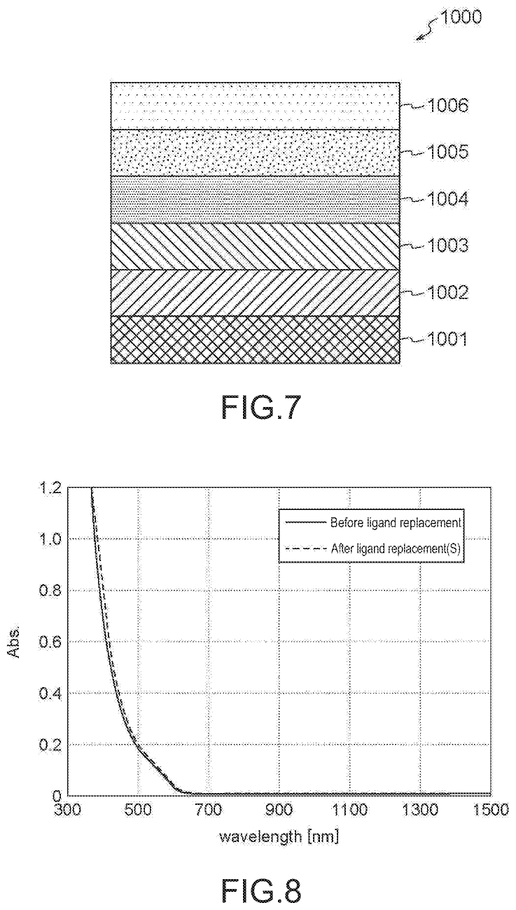

FIG. 7 shows an optical sensor 1000 including a semiconductor film 1004 prepared in Example 6. In this optical sensor 1000, a first electrode 1002 formed of indium-doped tin oxide is formed on a support substrate 1001 formed of a quartz substrate to have a thickness of 100 nm, and then, an electron transport layer 1003 formed of titanium oxide was formed on the first electrode 1002 to have a thickness of 20 nm. Next, the dimethylformamide dispersion liquid of sulfur-coordinated Znₓ₂CU_{y3}In_{z3}S_{(2x2+y3+3z3)/2} quantum dots was coated on the electron transport layer 1003 by a spin coat method to form the semiconductor film 1004 with a thickness of 100 nm. Finally, a hole transport layer 1005 formed of NiO was prepared to have a thickness of 20 nm, and a second electrode 1006 formed of indium-doped tin was deposited with a thickness of 100 nm to complete the optical sensor 1000 containing semiconductor nanoparticles.

### Example 7

### UV-Vis-NIR Spectra of Semiconductor Nanoparticles 7 (a Core Portion: ZnCuInS₃, a Shell Portion: ZnS) Before and After Ligand Exchange

1-dodecanethiol-coordinated semiconductor nanoparticles 7 (a core portion: ZnCuInS₃, a shell portion: ZnS) were treated with ammonium sulfide to exchange ligands, and thus, sulfur (S)-coordinated semiconductor nanoparticles 7 (a core portion: ZnCuInS₃, a shell portion: ZnS) were obtained.

(Measurement of UV-Vis-NIR Spectra and Results)

The UV-Vis-NIR spectra of the 1-dodecanethiol-coordinated semiconductor nanoparticles 7 and the sulfur (S)-coordinated semiconductor nanoparticles 7 were measured within the range of 300 to 1500 nm. FIG. 8 shows the results of the UV-Vis-NIR spectra of 1-dodecanethiol-coordinated semiconductor nanoparticles 7 and sulfur (S)-coordinated semiconductor nanoparticles 7. In FIG. 8, the horizontal axis represents the wavelength (nm) and the vertical axis represents abs. (=absorbance).

As shown in FIG. 8, it has been confirmed that the UV-Vis-NIR spectra of 1-dodecanethiol-coordinated semiconductor nanoparticles 7 and the UV-Vis-NIR spectra of sulfur (S)-coordinated semiconductor nanoparticles 7 are substantially equal to each other and there is no change in the UV-Vis-NIR spectra before and after the ligand exchange.

### Example 8

### Wavelength Selectivity of Semiconductor Nanoparticles 8 (ZnCuInS₃)

Five samples in which the Cu/Zn ratio (molar ratio) of semiconductor nanoparticles 8 (ZnCuInS₃) was changed in five stages were prepared (semiconductor nanoparticles 8-1 to 8-5). The Cu/Zn ratio (XRF: fluorescent X-ray analysis) of each of the five samples of semiconductor nanoparticles is shown in FIG. 10 (table). As shown in FIG. 10 (table), the molar ratio of Cu/Zn was changed from a sample a: 1.0/1.1 to a sample e: 1.0/30.6 in terms of the charging ratio at the time of synthesis.

(Measurement of UV-Vis-NIR Spectra and Results)

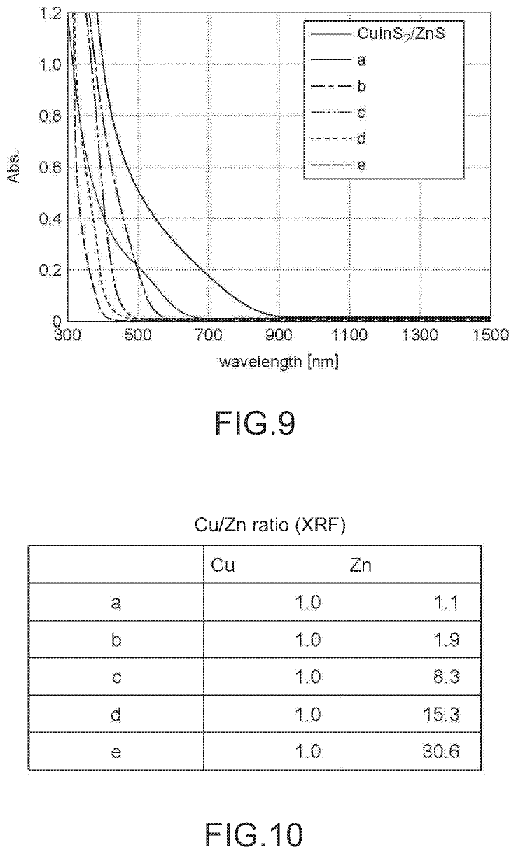

The UV-Vis-NIR spectra of the semiconductor nanoparticles 8-1 to 8-5 (i.e., samples a to e) and semiconductor nanoparticles 8-A in which a core portion is CuInS₂ and a shell portion ZnS were measured. The measurement was performed within the range of 300 to 1500 nm by dispersing the semiconductor nanoparticles in chloroform. FIG. 9 shows the results of the UV-Vis-NIR spectra of the semiconductor nanoparticles 8-1 to 8-5 and the UV-Vis-NIR spectra of the semiconductor nanoparticles 8-1. In FIG. 9, the horizontal axis represents the wavelength (nm) and the vertical axis represents the abs. (=absorbance).

As shown in FIG. 9, it has been confirmed that the wavelength adjustment from near infrared to ultraviolet is possible by adjusting the Cu/Zn ratio of the semiconductor nanoparticles 8 (ZnCuInS₃).

Note that embodiments of the present technology are not limited to the above-mentioned embodiments and examples, and various modifications can be made without departing from the essence of the present technology.

Further, the effects described herein are merely examples and are not limited, and additional effects may be exerted.

Further, the present technology may take the following configurations.

[1]

A semiconductor film containing semiconductor nanoparticles and sulfur,

the semiconductor nanoparticles having a core-shell structure, the core portion containing a compound represented by the following general formula (1), the shell portion containing ZnS, the sulfur coordinating to the semiconductor nanoparticles.

(Chem. 1)

Cu_{y1}In_{z1}A1_{(y1+3z1)/2} (1)

(In the general formula (1), y1 satisfies a relationship of 0<y1≤20, z1 satisfies a relationship of 0<z1≤20, and A1 represents S, Se, or Te.)

[2]

A semiconductor film containing semiconductor nanoparticles and sulfur,

the semiconductor nanoparticles having a core-shell structure, the core portion containing a compound represented by the following general formula (2), the shell portion containing ZnS, the sulfur coordinating to the semiconductor nanoparticles.

(Chem. 2)

Znₓ₁Cu_{y2}In_{z2}A2_{(2x1+y2+3z2)/2} (2)

(In the general formula (2), x1 satisfies a relationship of 0<x1≤20, y2 satisfies a relationship of 0<y2≤20, z2 satisfies a relationship of 0<z2≤20, and A2 represents S, Se, or Te.)

[3]

A semiconductor film containing semiconductor nanoparticles and sulfur,

the semiconductor nanoparticles containing a compound represented by the following general formula (3), the sulfur coordinating to the semiconductor nanoparticles.

(Chem. 3)

Znₓ₂Cu_{y3}In_{z3}A3_{(2x2+y3+3z3)/2} (3)

(In the general formula (3), x2 satisfies a relationship of 0<x2≤20, y3 satisfies a relationship of 0<y3≤20, z3 satisfies a relationship of 0<z3≤20, and A3 represents S, Se, or Te.)

[4]

An optical sensor, including:

the semiconductor film according to [1]; and

a first electrode and a second electrode that are disposed to face each other, in which

the semiconductor film is disposed between the first electrode and the second electrode.

[5]

An optical sensor, including:

the semiconductor film according to [2]; and

a first electrode and a second electrode that are disposed to face each other, in which

the semiconductor film is disposed between the first electrode and the second electrode.

[6]

An optical sensor, including: the semiconductor film according to [3]; and

a first electrode and a second electrode that are disposed to face each other, in which

the semiconductor film is disposed between the first electrode and the second electrode.

[7]

A solid-state image sensor, including:

at least the optical sensor according to [4] and a semiconductor substrate stacked for each of a plurality of one- or two-dimensionally arranged pixels.

[8]

A solid-state image sensor, including:

the optical sensor according to [4] and a semiconductor substrate stacked for each of a plurality of one- or two-dimensionally arranged pixels, in which

the optical sensor is for blue.

[9]

The solid-state image sensor according to [4], in which

a different optical sensor according to [4] is further stacked, and

the different optical sensor is for green.

[10]

The solid-state image sensor according to [9], in which

a still different optical sensor according to [4] is further stacked, and

the still different optical sensor is for red.

[11]

A solid-state image sensor, including:

at least the optical sensor according to [5] and a semiconductor substrate stacked for each of a plurality of one- or two-dimensionally arranged pixels.

[12]

A solid-state image sensor, including:

the optical sensor according to [5] and a semiconductor substrate stacked for each of a plurality of one- or two-dimensionally arranged pixels, in which

the optical sensor is for blue.

[13]

The solid-state image sensor according to [12], in which

a different optical sensor according to [5] is further stacked, and

the different optical sensor is for green.

[14]

The solid-state image sensor according to [13], in which

a still different optical sensor according to [5] is further stacked, and

the still different optical sensor is for red.

[15]

A solid-state image sensor, including:

at least the optical sensor according to [6] and a semiconductor substrate stacked for each of a plurality of one- or two-dimensionally arranged pixels.

[16]

A solid-state image sensor, including:

the optical sensor according to [6] and a semiconductor substrate stacked for each of a plurality of one- or two-dimensionally arranged pixels, in which

the optical sensor is for blue.

[17]

The solid-state image sensor according to [16], in which

a different optical sensor according to [6] is further stacked, and

the different optical sensor is for green.

[18]

The solid-state image sensor according to [17], in which

a still different optical sensor according to [6] is further stacked, and

the still different optical sensor is for red.

[19]

A solar battery, including: at least

the semiconductor film according to [1]; and

a first electrode and a second electrode that are arranged to face each other, in which

the semiconductor film is disposed between the first electrode and the second electrode.

[20]

A solar battery, including: at least

the semiconductor film according to [2]; and

a first electrode and a second electrode that are arranged to face each other, in which

the semiconductor film is disposed between the first electrode and the second electrode.

[21]

A solar battery, including: at least

the semiconductor film according to [3]; and

a first electrode and a second electrode that are arranged to face each other, in which

the semiconductor film is disposed between the first electrode and the second electrode.

[22]

An electronic apparatus, including:

at least the solid-state image sensor according to any one of [7] to [18].

### REFERENCE SIGNS LIST

10, 10A to 10B photoelectric conversion element

11 semiconductor substrate

12, 24, 25 insulation layer

20R red photoelectric conversion unit

20G green photoelectric conversion unit

20B blue photoelectric conversion unit

21R, 21G, 21B first electrode

22R, 22G, 22B semiconductor film (photoelectric conversion layer)

23R, 23G, 23B second electrode

26 crystalline silicon layer

27 organic semiconductor layer

31 protective layer

32 planarization layer

33 on-chip lens

110 a silicon layer

110R red storage layer

110G green storage layer

110B blue storage layer

1000 optical sensor

1001 support substrate

1002 first electrode

1003 electron transport layer 1003

1004 semiconductor film

1005 hole transport layer

1006 second electrode

1. A semiconductor film containing semiconductor nanoparticles and sulfur,
the semiconductor nanoparticles having a core-shell structure, the core portion containing a compound represented by the following general formula (1), the shell portion containing ZnS, the sulfur coordinating to the semiconductor nanoparticles.
(Chem. 1)
Cu_{y1}In_{z1}A1_{(y1+3z1)/2} (1)
(In the general formula (1), y1 satisfies a relationship of 0<y1≤20, z1 satisfies a relationship of 0<z1≤20, and A1 represents S, Se, or Te.)

2. A semiconductor film containing semiconductor nanoparticles and sulfur,
the semiconductor nanoparticles having a core-shell structure, the core portion containing a compound represented by the following general formula (2), the shell portion containing ZnS, the sulfur coordinating to the semiconductor nanoparticles.
(Chem. 2)
Znₓ₁Cu_{y2}In_{z2}A2_{(2x1+y2+3z2)/2} (2)
(In the general formula (2), x1 satisfies a relationship of 0<x1≤20, y2 satisfies a relationship of 0<y2≤20, z2 satisfies a relationship of 0<z2≤20, and A2 represents S, Se, or Te.)

3. A semiconductor film containing semiconductor nanoparticles and sulfur,
the semiconductor nanoparticles containing a compound represented by the following general formula (3), the sulfur coordinating to the semiconductor nanoparticles.
(Chem. 3)
Znₓ₂Cu_{y3}In_{z3}A3_{(2x2+y3+3z3)/2} (3)
(In the general formula (3), x2 satisfies a relationship of 0<x2≤20, y3 satisfies a relationship of 0<y3≤20, z3 satisfies a relationship of 0<z3≤20, and A3 represents S, Se, or Te.)

4. An optical sensor, comprising:
the semiconductor film according to claim 1; and
a first electrode and a second electrode that are disposed to face each other, wherein
the semiconductor film is disposed between the first electrode and the second electrode.

5. An optical sensor, comprising:
the semiconductor film according to claim 2; and
a first electrode and a second electrode that are disposed to face each other, wherein
the semiconductor film is disposed between the first electrode and the second electrode.

6. An optical sensor, comprising:
the semiconductor film according to claim 3; and
a first electrode and a second electrode that are disposed to face each other, wherein
the semiconductor film is disposed between the first electrode and the second electrode.

7. A solid-state image sensor, comprising:
at least the optical sensor according to claim 4 and a semiconductor substrate stacked for each of a plurality of one- or two-dimensionally arranged pixels.

8. A solid-state image sensor, comprising:
the optical sensor according to claim 4 and a semiconductor substrate stacked for each of a plurality of one- or two-dimensionally arranged pixels, wherein
the optical sensor is for blue.

9. The solid-state image sensor according to claim 8, wherein
a different optical sensor is further stacked, and
the different optical sensor is for green.

10. The solid-state image sensor according to claim 9, wherein
a still different optical sensor is further stacked, and
the still different optical sensor is for red.

11. A solid-state image sensor, comprising:
at least the optical sensor according to claim 5 and a semiconductor substrate stacked for each of a plurality of one- or two-dimensionally arranged pixels.

12. A solid-state image sensor, comprising:
the optical sensor according to claim 5 and a semiconductor substrate stacked for each of a plurality of one- or two-dimensionally arranged pixels, wherein
the optical sensor is for blue.

13. The solid-state image sensor according to claim 12, wherein
a different optical sensor is further stacked, and
the different optical sensor is for green.

14. The solid-state image sensor according to claim 13, wherein
a still different optical sensor is further stacked, and
the still different optical sensor is for red.

15. A solid-state image sensor, comprising:
at least the optical sensor according to claim 6 and a semiconductor substrate stacked for each of a plurality of one- or two-dimensionally arranged pixels.

16. A solid-state image sensor, comprising:
the optical sensor according to claim 6 and a semiconductor substrate stacked for each of a plurality of one- or two-dimensionally arranged pixels, wherein
the optical sensor is for blue.

17. The solid-state image sensor according to claim 16, wherein
a different optical sensor is further stacked, and
the different optical sensor is for green.

18. The solid-state image sensor according to claim 17, wherein
a still different optical sensor is further stacked, and
the still different optical sensor is for red.

19. A solar battery, comprising: at least
the semiconductor film according to claim 1; and
a first electrode and a second electrode that are arranged to face each other, wherein
the semiconductor film is disposed between the first electrode and the second electrode.

20. A solar battery, comprising: at least
the semiconductor film according to claim 2; and
a first electrode and a second electrode that are arranged to face each other, wherein
the semiconductor film is disposed between the first electrode and the second electrode.

21. A solar battery, comprising: at least
the semiconductor film according to claim 3; and
a first electrode and a second electrode that are arranged to face each other, wherein
the semiconductor film is disposed between the first electrode and the second electrode.
